(19) United States
(12) Patent Application Publication
(10) Pub. No.: US 2022/0415949 A1
(43) Pub. Date: Dec. 29, 2022

(54) SOLID-STATE IMAGING APPARATUS, METHOD FOR MANUFACTURING THE SAME, AND ELECTRONIC DEVICE

(71) Applicant: SUPERBVUE SOLUTIONS INC., Zhuhai (CN)

(72) Inventors: Shunsuke Tanaka, Yokohama (JP); Yuki Nobusa, Yokohama (JP)

(21) Appl. No.: 17/808,515

(22) Filed: Jun. 23, 2022

(30) Foreign Application Priority Data
Jun. 29, 2021 (JP) 2021-107386

(51) Int. Cl. H01L 27/146; H04N 5/33; H04N 5/369; H04N 9/04

(52) U.S. Cl. CPC H01L 27/14629; H04N 5/332; H04N 5/36963; H04N 9/04553; H01L 27/14645; H01L 27/14649; H01L 27/1462; H01L 27/14621; H01L 27/14623; H01L 27/14685

(57) ABSTRACT

A pixel portion includes photodiodes formed on a semiconductor substrate as photoelectric conversion portions, and includes: a high absorption layer (HA layer) for controlling a reflection component of incident light on one surface side of the photodiodes (photoelectric conversion portions), and re-diffusing the incident light in the photoelectric conversion portions, on one surface side of the photodiodes upon which light is incident; and a diffused light suppression structure for suppressing diffused light (caused by light scattering) in a light incident path toward one surface side of the photoelectric conversion portions including the high absorption layer. Due to this, a solid-state imaging apparatus capable of reducing crosstalk between pixels, achieving miniaturization of pixel size, reducing color mixing, and achieving high sensitivity and high performance can be realized.

### CROSS-REFERENCE TO RELATED APPLICATIONS

The present disclosure contains subject matter related to Japanese Patent Application JP 2021-107386 filed in the Japan Patent Office on Jun. 29, 2021, the entire contents of which being incorporated herein by reference.

### BACKGROUND

### 1. Technical Field

The present disclosure relates to a solid-state imaging apparatus, a method of manufacturing the solid-state imaging apparatus, and an electronic device.

### 2. Description of Related Art

Complementary metal oxide semiconductor (CMOS) image sensors have been provided for practical use as solid-state imaging apparatus (image sensor). The solid-state imaging apparatus uses a photoelectric conversion component that detects light and generates electric charges.

A CMOS image sensor generally uses three primary color filters (red (R), green (G) and blue (B)) or 4-color complementary color filters (cyan, magenta, yellow and green) to take color images.

Generally speaking, in a CMOS image sensor, pixels are individually equipped with a filter. The filters include four filters of a red (R) filter that mainly transmits red light, green (Gr, Gb) filters that mainly transmit green light, and a blue (B) filter that mainly transmits blue light which are arranged in a square as a subpixel group. The subpixel groups as unit RGB subpixel groups are arranged in a two-dimensional manner to form as multiple pixels.

In addition, the incident light entering a CMOS image sensor passes through a filter and is received by a photodiode. Since the photodiode receives light in a wavelength range (380 nm to 1100 nm) which is wider than a human visible region (about 380 nm to 780 nm) and generates signal charges, it will cause color mixing of infrared light components, and reduce color reproducibility. Accordingly, infrared light is generally removed by an infrared (IR) cut filter pre-set in a camera set. However, since the IR cut filter attenuates visible light by about 10% to 20%, it reduces sensitivity of the solid-state imaging apparatus, thereby resulting in deterioration of image quality.

As such, a CMOS image sensor (solid-state imaging apparatus) that does not use an IR cut filter has been provided (for example, referring to Patent Document 1). In this CMOS image sensor, the subpixel groups as unit RGBIR subpixel groups are arranged in a two-dimensional manner to form as multiple pixels, and in the subpixel group, four subpixels of a R subpixel with a red (R) filter that primarily transmits red light, a G subpixel including a green (G) filter that primarily transmits green light, a B subpixel including a blue (B) filter that primarily transmits blue light, and a dedicated near-infrared (NIR, e.g., 940 nm) subpixel that receives infrared light or a black-and-white infrared (M-NIR, e.g., 500 nm to 955 nm) subpixel that receives black and white (Monochrome: M) and infrared light, are arranged in a square. This CMOS image sensor functions as an NIR-RGB sensor that can obtain so-called NIR images and RGB images.

In this CMOS image sensor, the output signals of the subpixels that receive infrared light can be used to correct the output signals of the subpixels that receive red, green and blue light, without using an IR cut filter to achieve high color reproducibility.

However, in recent years, in CMOS image sensors, it is known to form a high absorption layer (hereinafter also sometimes referred to as HA) on the surface (Si surface) of the photodiodes which are photoelectric conversion portions, so as to improve the sensitivity in a wide wavelength range (e.g., referring to Patent Document 2).

These HA layers are formed on the Si surface on the incident light side formed with photodiodes, and the reflection component of incident light is controlled on the Si surface and diffused the incident light in the photodiodes again such that the sensitivity can be improved.

FIG. 1 is a schematic cross-sectional view of each constituent element in a pixel portion of a solid-state imaging apparatus (CMOS image sensor) having a unit RGB pixel group, and shows a high absorption layer arranged on one surface side of a substrate according to a first structure example. FIG. 2 is a schematic cross-sectional view of each constituent element in a pixel portion of a solid-state imaging apparatus (CMOS image sensor) having a unit RGB pixel group, and shows a high absorption layer arranged on one surface side according to a second structure example.

In the examples of FIGS. 1 and 2, the pixel portion of the CMOS image sensor 1, la includes an effective pixel area EPA1 for pixels to be photoelectrically converted, and an optical black area (OB) OBA1 arranged in a peripheral area of the effective pixel area EPA1. Additionally, in FIGS. 1 and 2, for ease of understanding, the red (R) pixel PXL1 including the photodiode PD1, the green (Gr) pixel or the near-infrared (NIR) pixel PXL2 including the photodiode PD2, the red (R) pixel PXL3 including the photodiode PD3, the green (Gr) pixel PXL4 including the photodiode PD4 in the effective pixel area EPA1 in the predetermined row, as well as the red (R) pixel PXL5 including the photodiode PD5 and the green (Gr) pixel or the near-infrared (NIR) pixel PXL6 including the photodiode PD6 in the optical black area OBA1 arranged in a row are shown.

In the CMOS image sensor 1, la, as shown in FIGS. 1 and 2, an element separation between adjacent photodiodes PD is performed by a deep trench isolation part (DTI) 1. In the CMOS image sensor 1, la, as shown in FIGS. 1 and 2, on the first substrate surface 2 of the photodiodes PD1 to PD6, a filter array 4 is disposed via a flat film 3. In addition, on the light incident side of each of the color filters 4(R) and 4(G) of the filter array 4, microlenses MCL1 to MCL6 of a microlens array 5 are disposed. Moreover, in the CMOS image sensors 1, la, as shown in FIGS. 1 and 2, a light-shielding film 60B of metal or the like, is formed in the flat film 3 of the optical black area OBA1 of the peripheral region so as to face the first substrate surface 2. Further, in the flat film 3 of the effective pixel area EPA1, a light shielding film 6E is formed at a position facing the DTI 1.

Additionally, in the CMOS image sensor 1 of FIG. 1, on the first substrate surface 2 of the photodiodes PD1 to PD6, a high absorption layer 7 is formed across the entire pixel portion including the effective pixel area EPA1 and the optical black area OBA1 of the peripheral region.

On the other hand, in the CMOS image sensor 1a of FIG. 2, the high absorption layer 7 is formed on the first substrate surface (one surface side) 2 of the photodiodes PD1 to PD4 in the effective pixel area EPA1 excluding the optical black area OBA1 in the peripheral area, respectively, in pixel units. In addition, the high absorption layer 7 is formed corresponding to the effective pixel area EPA1 of the pixel portion 20, and is not formed corresponding to the optical black (OB) area, i.e., the peripheral area.

According to the CMOS image sensor 1a of FIG. 2, the unnecessary radiation to the optical black area can be suppressed. Besides, crosstalk between pixels can be reduced, and it is possible to prevent deterioration of angular responsiveness.

### CITATION LIST

### Patent Literature

Patent Document 1: Japanese Patent Application Publication No. 2017-139286
Patent Document 2: Japanese Patent Application Publication No. 2020-27937

### SUMMARY

### Problems to be Solved by the Present Disclosure

In the above-mentioned CMOS image sensor 1 of FIG. 1, since the high absorption layer 7 having the HA structure is formed across the entire pixel portion including the effective pixel area EPA 1 and the optical black area OBA1 of the peripheral area, the HA structure on the surface of the pixel portion greatly suppresses the Si surface (photodiode surface) reflection, thereby helping to improve sensitivity.

However, since light is scattered in the Si direction in the HA structure, light leaks into adjacent pixels especially in the peripheral portion of the pixel (arrows (path)a and (path)c in FIG. 1). Additionally, there is also a concern that the light reflected on the surface of the HA layer will bounce back to the back-side metal (BSM), and the light leaks into the adjacent pixels (light leaks) (arrows (path)b and (path)d in FIG. 1). When such leakage of light occurs in the effective pixel area EPA1 (arrows (path)a and (path)b in FIG. 1), it causes deterioration of color mixing characteristics, and when leaking from the effective pixel into the optical black area OBA1 (arrows (path)c and (path)d in FIG. 1), a so-called “OB blackening” phenomenon occurs in which the black reference value of the optical black area OBA1 increases.

On the other hand, in the CMOS image sensor 1a of FIG. 2, basically, the HA layer is partially formed on the center portion of each pixel. The purpose of this arrangement is to suppress color mixing caused by the HA structure in the peripheral portion of the pixel adjacent to the peripheral pixel, or the HA structure of the optical black area OBA1. In addition, although this arrangement has the effect of reliably suppressing color mixing (arrows (path)a and (path)c in FIG. 2) caused by scattering components originating from the HA layer, since the HA layer is not formed in the peripheral portion, the reflection component on the Si surface increases, resulting in a decrease in sensitivity, which may be a cause of a decrease in sensitivity shading with respect to the incident angle. As such, the color mixing of the arrow (path)b and the arrow (path)d in FIG. 2 is larger than that of the CMOS image sensor 1 in FIG. 1.

Besides, in the CMOS image sensor 1a of FIG. 2, although the HA layer in the optical black area OBA1 is removed in order to prevent light from leaking into the optical black area OBA1, a plurality of nitride-based films is generally laminated on the HA layer for the purpose of preventing and/or suppressing reflection. This affects the amount of hydrogen supplied during hydrogen annealing (sinter), and often results in a difference in dark current between the pixel portion and the optical black region OBA1, resulting in one of the reasons for the abnormal picture quality such as a decrease in signal (blackened) or an increase in dark current. Specifically, when color mixing occurs in the optical black area OBA1, a spurious signal occurs in the optical black area OB1 even in the dark. For this reason, excessive correction is applied during AD conversion, and the signal becomes small (blackened). When the values of the dark current of the optical black area OBA1 and the dark current of the effective pixel area EPA are different, the dark current of the optical black area OBA1 will be higher than that of the effective pixel area EPA1. As a result, the signal amount of the effective pixel area EPA 1 becomes lower than actual due to excessive correction (blackened), and the dark current of the optical black area OBA1 is low. Therefore, the noise reduction is insufficient and finally the dark current of the effective pixel area increases.

As described above, in principle, the HA film sends the light reflected on the Si surface back to the photodiode side as scattered light, which causes color mixing between pixels of different colors. In addition, this color mixing is more likely to occur if the pixel pitch is narrow. Hence, although these HA structures have the effect of improving the sensitivity in the entire wavelength range, their development is limited to image sensors that capture near-infrared (NIR) light with relatively large pixel sizes. In addition, in recent years, the miniaturization of sets such as smartphones has been progressing, and the demand for a sensor with smaller pixel pitch and high sensitivity, or a CMOS image sensor that can simultaneously capture visible light and non-visible light such as infrared light without color mixing has been increasing.

The present disclosure provides a solid-state imaging apparatus, a method of manufacturing the solid-state imaging apparatus, and an electronic device capable of reducing crosstalk between pixels, miniaturizing pixel size, reducing color mixing, and achieving high sensitivity and high performance. In addition, the present disclosure provides a solid-state imaging apparatus, a method of manufacturing the solid-state imaging apparatus, and an electronic device, which can reduce crosstalk between pixels, can achieve miniaturization of pixel size, can reduce color mixing, can achieve high sensitivity and high performance, and thereby capable of receiving both visible light and non-visible light, and even capable of seeking to expand the application.

According to a first aspect of the present disclosure, a solid-state imaging apparatus comprises: a pixel portion in which a plurality of pixels, at least each for visible light and each for performing photoelectric conversion, are arranged in a matrix, the pixel portion including: a filter array arranged with at least a plurality of color filters for visible light; a plurality of photoelectric conversion portions for visible light corresponding to at least the plurality of color filters, provided with a function of photoelectric conversing light that passes through each of the color filters arranged on one surface side and outputting charges obtained by photoelectric conversion; a high absorption layer arranged on one surface side of the photoelectric conversion portions, for controlling a reflection component of incident light on a surface of the one surface side of the photoelectric conversion portions, and re-diffusing the incident light in the photoelectric conversion portions; and a diffused light suppression structure for suppressing diffused light in a light incident path toward one surface side of the photoelectric conversion portions including the high absorption layer.

According to a second aspect of the present disclosure, a method for manufacturing a solid-state imaging apparatus is provided, the solid-state imaging apparatus including: a pixel portion in which a plurality of pixels, at least each for visible light and each for performing photoelectric conversion, are arranged in a matrix, the pixel portion including: a filter array, a plurality of photoelectric conversion portions for visible light, a high absorption layer, and a diffused light suppression structure; as a step of forming the pixel portion, the method including the steps of: forming the filter array by arranging at least a plurality of color filters for visible light on one surface side of the plurality of photoelectric conversion portions for visible light; forming the plurality of photoelectric conversion portions for visible light as corresponding to at least the plurality of color filters and being provided with a function of photoelectric conversing light that passes through each of the color filters arranged on one surface side and outputting charges obtained by photoelectric conversion; forming on the one surface side of the photoelectric conversion portions, the high absorption layer for controlling a reflection component of incident light on a surface of the one surface side of the photoelectric conversion portions, and re-diffusing the incident light in the photoelectric conversion portions; and forming the diffused light suppression structure for suppressing diffused light in a light incident path toward one surface side of the photoelectric conversion portions including the high absorption layer.

According to a third aspect of the present disclosure, an electronic device includes: a solid-state imaging apparatus; and an optical system configured for imaging an object in the solid-state imaging apparatus, the solid-state imaging apparatus including: a pixel portion in which a plurality of pixels, at least each for visible light and each for performing photoelectric conversion, are arranged in a matrix, the pixel portion including: a filter array arranged with at least a plurality of color filters for visible light; a plurality of photoelectric conversion portions for visible light corresponding to at least the plurality of color filters, provided with a function of photoelectric conversing light that passes through each of the color filters arranged on one surface side and outputting charges obtained by photoelectric conversion; a high absorption layer arranged on one surface side of the photoelectric conversion portions, for controlling a reflection component of incident light on a surface of the one surface side of the photoelectric conversion portions, and re-diffusing the incident light in the photoelectric conversion portions; and a diffused light suppression structure for suppressing diffused light in a light incident path toward one surface side of the photoelectric conversion portions including the high absorption layer.

### Effects of the Present Disclosure

According to the present disclosure, crosstalk between pixels can be reduced, and miniaturization of pixel size can be achieved. Moreover, color mixing can be reduced, and high sensitivity and high performance can be achieved. Further, according to the present disclosure, crosstalk between pixels can be reduced, and miniaturization of pixel size can be achieved. In addition, color mixing can be reduced, and high sensitivity and high performance can be achieved. Accordingly, the present disclosure can receive both visible light and non-visible light, and can even seek to expand the application.

### BRIEF DESCRIPTION OF DRAWINGS

FIG. 1 is a schematic cross-sectional view of each constituent element in a pixel portion of a solid-state imaging apparatus (CMOS image sensor) having a unit RGB pixel group, and shows a high absorption layer arranged on one surface side of a substrate according to a first structure example.

FIG. 2 is a schematic cross-sectional view of each constituent element in a pixel portion of a solid-state imaging apparatus (CMOS image sensor) having a unit RGB pixel group, and shows a high absorption layer arranged on one surface side according to a second structure example.

FIG. 3 is a block diagram showing a structure example of the solid-state imaging apparatus according to a first embodiment of the present disclosure.

FIG. 4 is a circuit diagram showing a structure example of the pixel portion of the solid-state imaging apparatus according to the first embodiment of the present disclosure.

FIG. 5 is a schematic cross-sectional view of each constituent element in the pixel portion of the solid-state imaging apparatus (CMOS image sensor) according to the first embodiment of the present disclosure.

FIG. 6 is a schematic cross-sectional view of each constituent element in a pixel portion of a solid-state imaging apparatus (CMOS image sensor) according to a second embodiment of the present disclosure.

FIG. 7 is a schematic cross-sectional view of each constituent element in a pixel portion of a solid-state imaging apparatus (CMOS image sensor) according to a third embodiment of the present disclosure.

FIG. 8 is a diagram for explaining a first structure example of a scattering suppression portion in a high absorption layer according to the third embodiment of the present disclosure.

FIG. 9 is a diagram for explaining a second structure example of a scattering suppression portion in a high absorption layer according to the third embodiment of the present disclosure.

FIG. 10 is a schematic cross-sectional view of each constituent element in a pixel portion of a solid-state imaging apparatus (CMOS image sensor) according to a fourth embodiment of the present disclosure.

FIG. 11 is a schematic cross-sectional view of each constituent element in a pixel portion of a solid-state imaging apparatus (CMOS image sensor) according to a fifth embodiment of the present disclosure.

FIG. 12 is schematic cross-sectional view of each constituent element in a pixel portion of a solid-state imaging apparatus (CMOS image sensor) according to a sixth embodiment of the present disclosure.

FIG. 13 is schematic cross-sectional view of each constituent element in a pixel portion of a solid-state imaging apparatus (CMOS image sensor) according to a seventh embodiment of the present disclosure.

FIG. 14 is a schematic cross-sectional view of each constituent element in a pixel portion of a solid-state imaging apparatus (CMOS image sensor) according to an eighth embodiment of the present disclosure.

FIG. 15 is a schematic cross-sectional view of each constituent element in a pixel portion of a solid-state imaging apparatus (CMOS image sensor) according to a ninth embodiment of the present disclosure.

FIG. 16 is a graph showing the quantum efficiency (%) performance with respect to the wavelength of incident light of the solid-state imaging apparatus (CMOS image sensor) according to the ninth embodiment of the present disclosure.

FIGS. 17A and 17B are diagrams showing a schematic arrangement example of each constituent element in the pixel portion of the solid-state imaging apparatus (CMOS image sensor) in a plane view according to a tenth embodiment of the present disclosure.

FIGS. 18A and 18B are diagrams showing a schematic arrangement example of each constituent element in the pixel portion of the solid-state imaging apparatus (CMOS image sensor) in a plane view according to an eleventh embodiment of the present disclosure.

FIG. 19 is a diagram showing a structure example of an electronic device to which the solid-state imaging apparatus according to the present disclosure is applied.

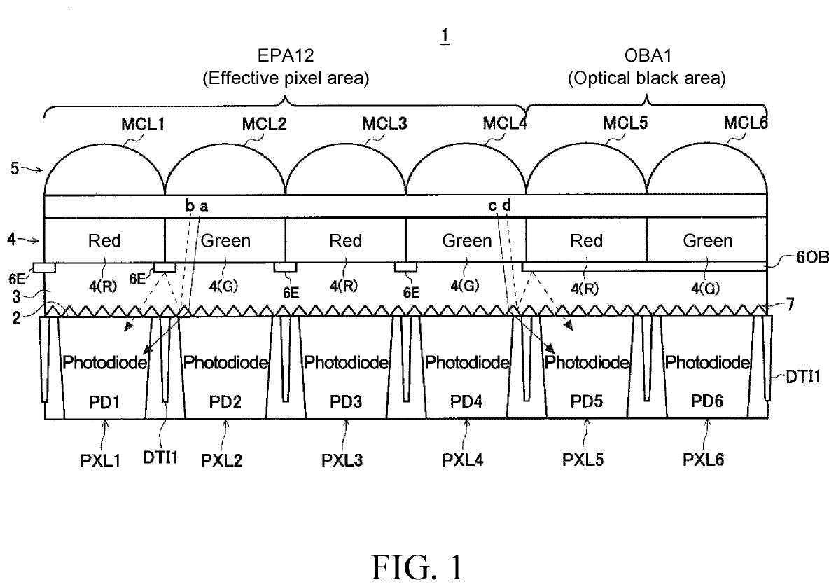

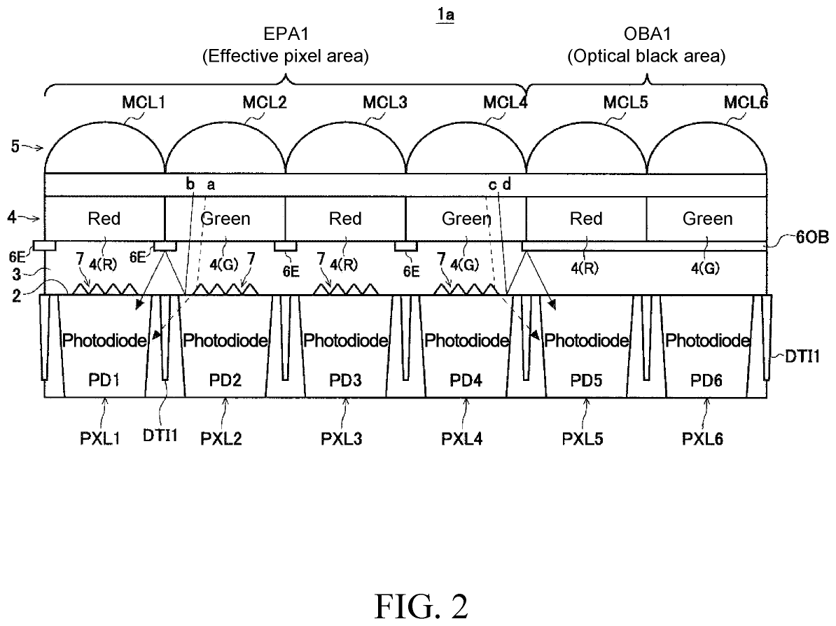

### DETAILED DESCRIPTION

The embodiments of the present disclosure are related to the drawings for description hereinafter.

### First Embodiment

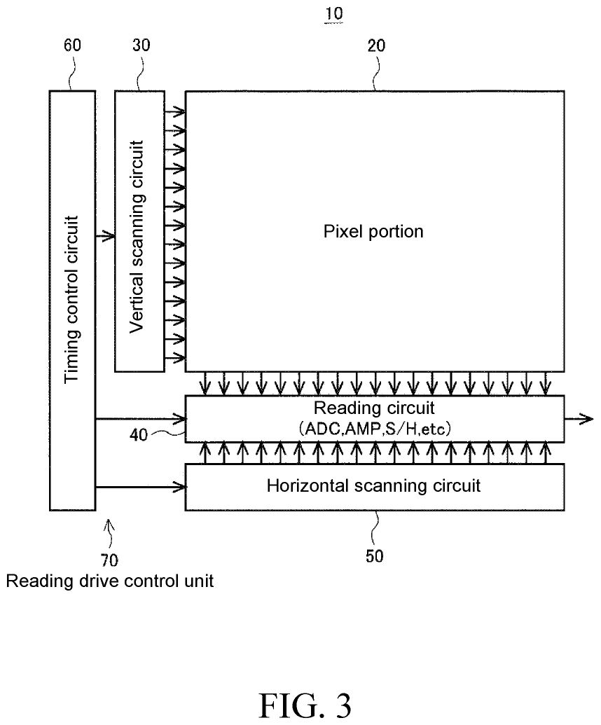

FIG. 3 is a block diagram showing a structure example of the solid-state imaging apparatus according to a first embodiment of the present disclosure. According to this embodiment, the solid-state imaging apparatus 10 is constituted by, for example, a CMOS image sensor.

As shown in FIG. 3, the solid-state imaging apparatus 10 mainly includes a pixel portion 20 as an imaging portion, a vertical scanning circuit (a row scanning circuit) 30, a reading circuit (a column reading circuit) 40, a horizontal scanning circuit (a column scanning circuit) 50 and a timing control circuit 60. In addition, among these components, for example, the vertical scanning circuit 30, the reading circuit 40, the horizontal scanning circuit 50 and the timing control circuit 60 together constitute a reading drive control unit 70 of a pixel signal.

According to the first embodiment, the solid-state imaging apparatus 10 has a pixel portion 20 in which a plurality of pixels, each for visible light including R, G and B and each for performing photoelectric conversion, are arranged in a matrix. The pixel portion 20 includes: a filter array arranged with a plurality of color filters for visible light (R, G, B); a plurality of photoelectric conversion portions (photodiodes PD) for visible lights (R, G, B) which correspond to the plurality of color filters, the photoelectric conversion portions (photodiodes PD) being provided with a function of photoelectric conversing the lights that pass through each of the color filters arranged on one surface side of a semiconductor substrate and outputting charges obtained by photoelectric conversion; a high absorption layer (HA layer) arranged on one surface side (one side of the semiconductor substrate) of the photoelectric conversion portions (PD), for controlling a reflection component of incident light on a surface of the one surface side of the photoelectric conversion portions PD, and re-diffusing the incident light in the photoelectric conversion portions PD; and a diffused light suppression structure for suppressing diffused light caused by scattering in a light incident path toward one surface side of the photoelectric conversion portions including the high absorption layer.

In the first embodiment, the diffused light suppression structure includes a flat film formed between one surface side of the photoelectric conversion portions and a light exit surface side of the filters. The diffused light suppression structure includes a guided wave structure for redirecting diffused light to the pixels in an upper part of the element separation portion of each pixel. The guided wave structure includes a back-side separation portion, and the back-side separation portion is formed to include the space between adjacent filters so as to separate a plurality of adjacent pixels at least in light incident portions of the photoelectric conversion portions. In addition, the flat film is formed to have a thickness equal to a thickness of the high absorption layer, so as to narrow the gap between the element separation portion (DTI, etc.) in the semiconductor substrate (in Si) and the back-side separation portion (BSM, etc.) on the upper layer of the element separation portion, and make the distance thereof substantially close to zero. Further, in order to narrow the gap between the element separation portion (DTI, etc.) in the semiconductor substrate (in Si) and the back-side separation portion (BSM, etc.) on the upper layer of the element separation portion, and make the distance thereof substantially close to zero, a guided wave structure including a back-side separation portion such as BSM is arranged to be embedded between adjacent color filters. In the first embodiment, the flat film is formed to have a thickness equal to a thickness of the high absorption layer, and in the element separation region between adjacent pixels, a formation region of the element separation portion and a formation region of the back-side separation portion are formed in a state of being close to each other (the distance is substantially zero) via the flat film.

Moreover, in the first embodiment of the present disclosure, the pixel portion includes: an effective pixel area in which pixels are to be photoelectrically converted; and a peripheral area arranged around the effective pixel area. In addition, in the first embodiment of the present disclosure, the unit pixel group is formed as a unit RGB pixel group.

Hereinafter, after an outline of the arrangement and function of each part of the solid-state imaging apparatus 10 is described, the specific configuration, arrangement and the like of the pixels will be described in detail.

(Configurations of the Pixel Portion 20 and the Pixels PXL)

The pixel portion 20 is arranged with a plurality of pixels including photodiodes (photoelectric conversion units) and in-pixel amplifiers in a two-dimensional shape (N columns×M rows).

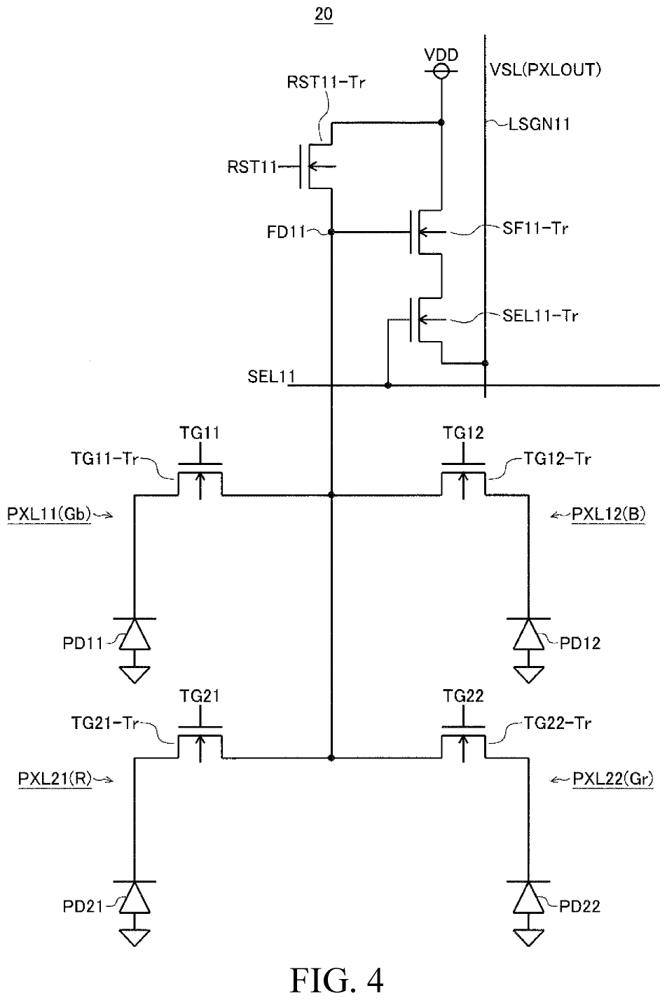

FIG. 4 is a circuit diagram showing a structure example of the solid-state imaging apparatus according to the first embodiment of the present disclosure. Here, the example in which four pixels share one floating diffusion layer is shown as an example.

The pixel portion 20 in FIG. 4 is configured by arranging four pixels PXL11, PXL12, PXL21, PXL22 in a 2×2 square.

The pixel PXL11 is composed of a photodiode PD11 and a transfer transistor TG11-Tr. The pixel PXL12 is composed of a photodiode PD12 and a transfer transistor TG12-Tr. The pixel PXL21 is composed of a photodiode PD21 and a transfer transistor TG21-Tr. The pixel PXL22 is composed of a photodiode PD22 and a transfer transistor TG22-Tr.

In addition, as an example, in the pixel portion 20, four pixels PXL11, PXL12, PXL21, PXL22 share a floating diffusion layer, a reset transistor RST11-Tr, a source follower transistor SF11-Tr and a select transistor SEL11-Tr.

In such pixel arrangement, when the unit pixel groups are arranged in a Bayer pattern, the pixel PXL11 is formed as a Gb pixel, the pixel PXL12 is formed as a B pixel, the pixel PXL21 is formed as an R pixel, and the pixel PXL 22 is formed as a Gr pixel. For example, the photodiode PD11 of the pixel PXL11 functions as a first green (Gb) photoelectric conversion portion. The photodiode PD12 of the pixel PXL12 functions as a blue (B) photoelectric conversion portion. The photodiode PD21 of the pixel PXL21 functions as a red (R) photoelectric conversion portion. The photodiode PD22 of the pixel PXL22 functions as a second green (Gr) photoelectric conversion portion.

Generally speaking, the achieved saturation sensitivity of the photodiode PD of each pixel varies depending on the color. For example, the sensitivities of the G-pixel photodiodes PD11, PD22 are higher than the sensitivities of the B-pixel photodiode PD12 and the R-pixel photodiode PD21.

For the photodiodes PD11, PD12, PD21 and PD22, for example, embedded photodiodes (PPD) are used. Since there are surface levels caused by defects such as dangling bonds on the surface of the substrate on which the photodiodes PD11, PD12, PD21 and PD22 are formed, a lot of charges (dark current) are generated due to thermal energy such that correct signals cannot be read. In an embedded photodiode (PPD), by embedding the charge storage part of the photodiode PD in the substrate, it is possible to reduce dark current mixed into a signal.

The photodiodes PD11, PD12, PD21 and PD22 generate and accumulate signal charges (electrons herein) corresponding to the amount of incident light. In the following, descriptions are made on the case where the signal charges are electrons and each transistor is an n-type transistor. However, alternatively, the signal charges can be holes, and/or each transistor can be a p-type transistor.

In the first embodiment of the present disclosure, the photodiodes PD11, PD12, PD21, PD22 are provided with a filter array on the first substrate surface side, as described later. On one surface side (first substrate surface side) of the photodiodes PD belonging to the photoelectric conversion portions, a high absorption layer is formed across the entire areas of the optical black area of the peripheral region and the effective pixel area.

The transfer transistor TG11-Tr is connected between the photodiode PD11 and the floating diffusion FD11, and is controlled by the control signal TG11. The transfer transistor TG11-Tr is under the control of the reading drive control unit 70, and during the period of the control signal TG11 in predetermined high level (H), the transfer transistor TG11-Tr is selected and becomes in the “on” state such that the charges (electrons) which are photoelectric converted and accumulated by the photodiode PD11 are transferred to the floating diffusion FD11.

The transfer transistor TG12-Tr is connected between the photodiode PD12 and the floating diffusion FD11, and is controlled by the control signal TG12. The transfer transistor TG12-Tr is under the control of the reading drive control unit 70, and during the period of the control signal TG12 in predetermined high level (H), the transfer transistor TG12-Tr is selected and becomes in the “on” state such that the charges (electrons) which are photoelectric converted and accumulated by the photodiode PD12 are transferred to the floating diffusion FD11.

The transfer transistor TG21-Tr is connected between the photodiode PD21 and the floating diffusion FD11, and is controlled by the control signal TG21. The transfer transistor TG21-Tr is under the control of the reading drive control unit 70, and during the period of the control signal TG21 in predetermined high level (H), the transfer transistor TG21-Tr is selected and becomes in the “on” state such that the charges (electrons) which are photoelectric converted and accumulated by the photodiode PD21 are transferred to the floating diffusion FD11.

The transfer transistor TG22-Tr is connected between the photodiode PD22 and the floating diffusion FD11, and is controlled by the control signal TG22. The transfer transistor TG22-Tr is under the control of the reading drive control unit 70, and during the period of the control signal TG22 in predetermined high level (H), the transfer transistor TG22-Tr is selected and becomes in the “on” state such that the charges (electrons) which are photoelectric converted and accumulated by the photodiode PD22 are transferred to the floating diffusion FD11.

As shown in FIG. 4, the reset transistor RST11-Tr is connected between the power line VDD (or power supply potential) and the floating diffusion FD11, and is controlled by the control signal RST11. The reset transistor RST11-Tr is under the control of the reading drive control unit 70, and for example, during the period of the control signal RST11 in predetermined high level (H) when conducting reading scanning, the reset transistor RST11-Tr is selected and becomes in the “on” state and the floating diffusion FD11 is reset to the potential of the power line VDD.

The source follower transistor SF11-Tr and the select transistor SEL11-Tr are connected in series between the power line VDD and the vertical signal line LSGN11. The gate of the source follower transistor SF11-Tr is connected to the floating diffusion FD11, and the select transistor SEL11-Tr is controlled by the control signal SEL11. The select transistor SEL11-Tr is selected and becomes in the “on” state during the high level H period of the control signal SEL11. Hence, the source follower transistor SF11-Tr converts the charges of the floating diffusion FD11 into a voltage signal by means of the gain of the charge amount (potential), and outputs the read voltage (signal) VSL (PXLOUT) of the column output of the voltage signal to the vertical signal line LSGN11.

The vertical scanning circuit 30 drives the pixels in the shutter row and the reading row through row scanning control lines according to the control of the timing control circuit 60. In addition, the vertical scanning circuit 30 outputs the row select signal for the row address of the read row for reading the signal and the shutter row for resetting the charges accumulated in the photodiode PD according to the address signal.

In a normal pixel reading operation, shutter scanning is performed by driving of the vertical scanning circuit 30 by the reading drive control unit 70, and then reading scanning is performed.

The reading circuit 40 may also be configured to include a plurality of column signal processing circuits (not shown) corresponding to the column outputs of the pixel portions 20, and perform column parallel processing by the plurality of column signal processing circuits.

The reading circuit 40 may include a correlated double sampling (CDS) circuit or an analog-digital converter (ADC), an amplifier (AMP) and a sample hold (S/H) circuit.

The horizontal scanning circuit 50 scans the signals processed by a plurality of column signal processing circuits such as the ADC of the reading circuit 40, transmits the signals in a horizontal direction, and outputs the signals to the signal processing circuit not shown.

The timing control circuit 60 generates timing signals required for signal processing such as the pixel portion 20, the vertical scanning circuit 30, the reading circuit 40 and the horizontal scanning circuit 50.

In summary, the outline of the configuration and function of each part of the solid-state imaging apparatus 10 has been described. Subsequently, the specific configuration of the pixel arrangement of the first embodiment will be described.

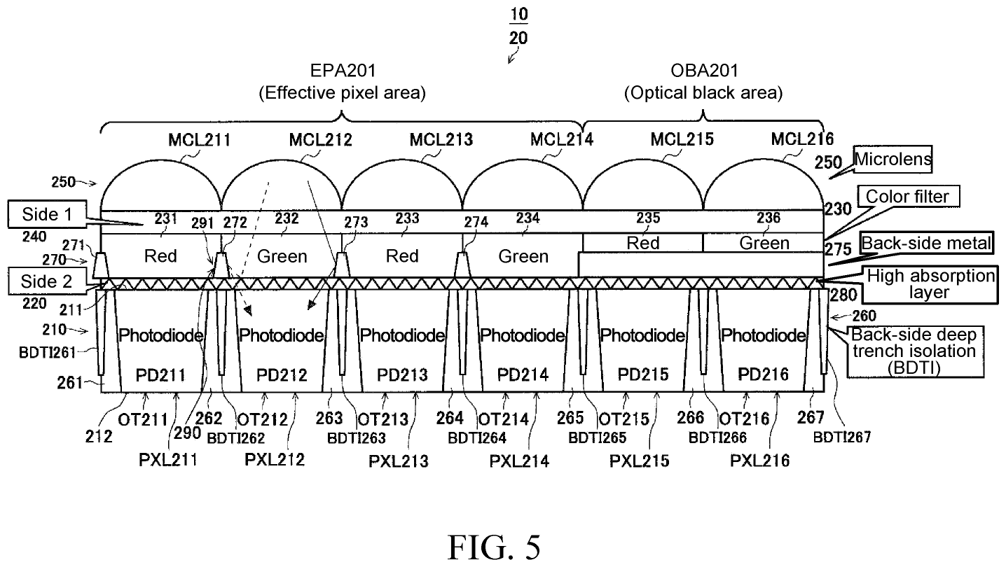

FIG. 5 is a schematic cross-sectional view of each constituent element in a pixel portion of a solid-state imaging apparatus (CMOS image sensor) according to the first embodiment of the present disclosure. For ease of understanding, the pixel portion 20 in FIG. 5 is a schematic cross-sectional view showing an example of a row in which the R pixels belonging to the R pixel PXL21 and the Gr pixels belonging to the pixel PXL22 are alternately arranged.

The pixel portion 20 of FIG. 5 is constituted by the following as main elements: a semiconductor substrate 210, a flat film 220, a filter array 230, a second flat film 240, a microlens array 250, an element separation portion 260, a back-side separation portion 270, a high absorption layer 280 and a diffused light suppression structure 290.

In the example of FIG. 5, the photodiodes PD211 to PD216 are formed on the semiconductor substrate 210 as photoelectric conversion portions. In addition, the one surface side of the photodiodes PD211 to PD216 that are photoelectric conversion portions on which the light is incident, is composed of the following: a high absorption layer (HA layer)280 for controlling a reflection component of incident light on a surface of the one surface side of the photodiodes (photoelectric conversion portions) PD211 to PD216; and a diffused light suppression structure 290 for suppressing diffused light (caused by scattering) in a light incident path toward one surface side of the photoelectric conversion portions including the high absorption layer 280. The high absorption layer 280 has a function of absorbing a part of the incident light, such as total reflection, and making the light incident on the specific photodiodes PD211 to PD216 from one surface side. For example, the high absorption layer 280 has a reflection absorbing structure that suppresses total reflection by scattering or the like.

In the first embodiment of the present disclosure, the diffused light suppression structure 290 includes a flat film 220 formed between one surface side of the photodiodes PD211 to PD216 and a light exit surface side of each color filter of the filter array 230. The diffused light suppression structure 290 includes a guided wave structure 291 that redirects diffused light to the pixels at the upper part of the element separation portion 260 (261 to 267) of each pixel. The guided wave structure 291 includes a back-side separation portion 270, and the back-side separation portion 270 is formed to include the space between adjacent filters so as to separate a plurality of adjacent pixels in light incident portions of the photodiodes PD211 to PD216 which belong to the photoelectric conversion portions.

Moreover, the flat film 220 is formed to have a thickness equal to a thickness of the high absorption layer 280, so as to narrow the gap between the element separation portions (BDTI, etc.) 261 to 267 in the semiconductor substrate 210 (in Si) and the back-side separation portion (BSM, etc.) 271 to 275 on the upper layer of the element separation portion 261 to 267, and make the distance thereof substantially close to zero. In addition, in order to narrow the gap between the element separation portion (BDTI, etc.) 261 to 267 in the semiconductor substrate 210 (in Si) and the back-side separation portion (BSM, etc.) 271 to 274 on the upper layer of the element separation portion 216 to 267 and make the distance thereof substantially close to zero, the guided wave structure 291 including the back-side separation portion such as a BSM is arranged to be embedded between adjacent color filters. In the first embodiment of the present disclosure, the flat film 220 is formed to have a thickness equal to the thickness of the high absorption layer 280. Moreover, in the element separation region between adjacent pixels, the formation region of the element separation portion 261 to 267 and the formation region of the back-side separation portion 271 to 274 are formed in a state of being close to each other (the distance is substantially zero) via the flat film 220.

Here, a more specific arrangement example of the pixel portion 20 in the solid-state imaging apparatus 10 of the first embodiment will be described in relation to FIG. 5.

In the example of FIG. 5, the pixel portion 20 of the solid-state imaging apparatus 10 is constituted by including the following: an effective pixel area EPA201 for pixels to be photoelectrically converted; and an optical black area OBA201 arranged in the peripheral area of the effective pixel area EPA201. Additionally, in FIG. 5, for the convenience of understanding, the red (R) pixel PXL211 including the photodiode PD211, the green (Gr) pixel PXL212 including the photodiode PD212, the red (R) pixel PXL213 including the photodiode PD213, the green (Gr) pixel PXL214 including the photodiode PD214 in the effective pixel area EPA201 in the predetermined row, as well as the red (R) pixel PXL215 including the photodiode PD215 and the green (Gr) pixel PXL216 including the photodiode PD216 in the optical black area OBA201 arranged in a row are shown.

In the solid-state imaging apparatus 10 of FIG. 5, an element separation between adjacent photodiodes PD is performing by including a back-side deep trench isolation (BDTI) in the element isolation area EIA. In the example of FIG. 5, the element separation between the photodiode PD211 of the effective pixel area EPA201 and the adjacent-to-left side photodiode PD210 in FIG. 5 (not shown) is conducted in the element separation portion 261 by including the BDTI 261. The element separation between the photodiode PD211 and the photodiode PD212 of the effective pixel area EPA201 is conducted in the element separation portion 262 by including the BDTI 262. The element separation between the photodiode PD212 and the photodiode PD213 of the effective pixel area EPA201 is conducted in the element separation portion 263 by including the BDTI 263. The element separation between the photodiode PD213 and the photodiode 214 of the effective pixel area EPA201 is conducted in the element separation portion 264 by including the BDTI 264. The element separation between the photodiode PD214 of the effective pixel area EPA201 and the photodiode PD215 of the optical black area OBA201 is conducted in the element separation portion 265 by including the BDTI 265. The element separation between the photodiode PD215 and the photodiode PD216 of the optical black area OBA201 is conducted in the element separation portion 266 by including the BDTI 266. The element separation between the photodiode PD216 and the adjacent-to-right-side photodiode PD217 in FIG. 5 (not shown) of the optical black area OBA201 is conducted in the element separation portion 267 by including the BDTI 267.

In the solid-state imaging apparatus 10 of FIG. 5, the photodiodes PD211 to PD216 serving as the photoelectric conversion portions are formed and embedded in the semiconductor substrate 210 including the first substrate surface 211 side (one surface side) and the second substrate surface 212 side (the other surface side), and formed to have a photoelectric conversion function and a charge accumulation function of the received light. On the second substrate surface 212 side (the other surface side) of the photodiodes PD211 to PD216 serving as the photoelectric conversion portions, outputting portions OT211 to OT216 including outputting transistors for outputting signals corresponding to charges that are photoelectric converted and accumulated are formed.

In the solid-state imaging apparatus 10 of FIG. 5, a light absorption layer 280 is arranged on the first substrate surface 211 of the element separation portion 261, the photodiode PD 211, the element separation portion 262, the photodiode PD212, the element separation portion 263, the photodiode PD213, the element separation portion 264, the photodiode PD214, the element separation portion 265, the photodiode PD215, the element separation portion 266 and the photodiode PD216. In addition, the flat film 220 formed to have the same thickness as the high absorption layer 280 is arranged to be laminated on the high absorption layer 280, and the filter array 230 is arranged to be laminated on the flat film 220. Further, the light incident side of each of the color filters 231 (R), 232 (Gr), 233 (R), 234 (Gr), 235 (R) and 236 (Gr) of the filter array 230 is arranged with the microlenses MCL211, MCL212, MCL213, MCL214, MCL215 and MCL216 of the microlens array 250 as the optical portion (lens portion).

As described above, in the first embodiment of the present disclosure, the diffused light suppression structure 290 includes a flat film 220 formed between one surface side of the photodiode PD211 to PD216 and a light exit surface side of each color filter of the filter array 230, and includes a back-side separation portion (e.g., BSM) 271 to 275 for redirecting diffused light to the pixels in an upper part of the element separation portion 260 (261 to 267) of each pixel.

In the example of FIG. 5, a BSM 271 having a back-side separation function and having a substantially trapezoidal cross-sectional shape is arranged on the upper layer of the trench isolation BDTI 261 of the element separation portion 261 between the color filter 231 (R) on the photodiode PD211 of the effective pixel area EPA 201 and the adjacent-to-left-side color filter (Gr) on the photodiode PD 210 in FIG. 5 (not shown). A BSM 272 having a back-side separation function and having a substantially trapezoidal cross-sectional shape is arranged on the upper layer of the trench isolation BDTI 262 of the element separation portion 262 between the color filter 231 (R) on the photodiode PD211 and the color filter 232 (Gr) on the photodiode PD212 of the effective pixel area EPA 201. A BSM 273 having a back-side separation function and having a substantially trapezoidal cross-sectional shape is arranged on the upper layer of the trench isolation BDTI 263 of the element separation portion 263 between the color filter 232 (Gr) on the photodiode PD212 and the color filter 233 (R) on the photodiode PD 213 of the effective pixel area EPA 201. A BSM 274 having a back-side separation function and having a substantially trapezoidal cross-sectional shape is arranged on the upper layer of the trench isolation BDTI 264 of the element separation portion 264 between the color filter 233 (R) on the photodiode PD213 and the color filter 234 (Gr) on the photodiode PD214 of the effective pixel area EPA 201.

Additionally, a high absorption layer 280 is arranged on the first substrate surface 211 of the element separation portion 265, the photodiode PD215, the element separation portion 266, the photodiode PD216 and the element separation portion 267 of the optical black area OBA1, and the flat film 280 formed to have the same thickness as the high absorption layer 280 is arranged in a manner of being laminated on the high absorption layer 280. Besides, a light-shielding film 275 that also functions as a BSM is formed so as to be laminated between the flat film 220 and the color filter 235 (R) and between the flat film 220 and the color filter 236 (Gr). In the first embodiment of the present disclosure, the light-shielding film 275 is formed by being incorporated in the filter array 230.

As described above, in the first embodiment of the present disclosure, the flat film 220 is formed to have a thickness equal to a thickness of the high absorption layer 280, so as to narrow the gap between the element separation portion (BDTI, etc.) 261 to 267 in the semiconductor substrate 210 (in Si) and the back-side separation portion (BSM, etc.) 271 to 274 on the upper layer of the element separation portion 261 to 267, and make the distance thereof substantially close to zero. Further, in order to narrow the gap between the element separation portion (BDTI, etc.) 261 to 267 in the semiconductor substrate 210 (in Si) and the back-side separation portion (BSM, etc.) 271 to 274 on the upper layer of the element separation portion 261 to 267, and make the distance thereof substantially close to zero, a guided wave structure 291 including a back-side separation portion such as BSM is arranged to be embedded between adjacent color filters. In the first embodiment, the flat film 220 is formed to have a thickness equal to a thickness of the high absorption layer 280, and in the element separation region between adjacent pixels, a formation region of the element separation portion 261 to 267 and a formation region of the back-side separation portion 271 to 277 are formed in a state of being close to each other (the distance is substantially zero) via the flat film 220.

In the pixel portion 20, most of the incident light collected by the microlens MCL and introduced into the second flat film 240 and filter array 230 is incident on the high absorption layer 280, and the reflection component of the incident light is controlled on the surface of one surface side of the photodiodes (photoelectric conversion portions) PD211 to PD216, and the incident light is re-diffused in the photodiodes PD (photoelectric conversion portions). Besides, diffused light in the light incident path (caused by light scattering) toward one surface side of the photodiode PD (photoelectric conversion portion) including the high light absorption layer 280 is reflected toward the surface side of the corresponding photodiode by the BSM 271 to 274 such that the diffused light in the incident light is controlled.

In addition, each color pixel having the above-mentioned structure may have a specific responsiveness not only in the visible range (400 nm to 700 nm) but also in the near-infrared (NIR) region (800 nm to 1000 nm).

To sum up, according to the first embodiment of the present disclosure, in the solid-state imaging apparatus 10, the pixel portion 20 is formed with the photodiodes PD211 to PD216 as photoelectric conversion portions in the semiconductor substrate 210. Additionally, the one surface side of the photodiodes PD211 to PD216 that are photoelectric conversion portions on which the light is incident, is composed of the following: a high absorption layer (HA layer)280 for controlling a reflection component of incident light on a surface of the one surface side of the photodiodes (photoelectric conversion portions) PD211 to PD216; and a diffused light suppression structure 290 for suppressing diffused light (caused by scattering) in a light incident path toward one surface side of the photoelectric conversion portions including the high absorption layer 280. The high absorption layer 280 has a function of absorbing a part of the incident light, such as total reflection, and making the light incident on the specific photodiodes PD211 to PD216 from one surface side. For example, the high absorption layer 280 has a reflection absorbing structure that suppresses total reflection by scattering or the like. The diffused light suppression structure 290 includes a flat film 220 formed between one surface side of the photodiodes PD211 to PD216 and a light exit surface side of each color filter of the filter array 230. The diffused light suppression structure 290 includes a guided wave structure 291 that redirects diffused light to the pixels at the upper part of the element separation portion 260 (261 to 267) of each pixel. The guided wave structure 291 includes a back-side separation portion 270 (271 to 274), and the back-side separation portion 270 (271 to 274) is formed to include the space between adjacent filters so as to separate a plurality of adjacent pixels in light incident portions of the photodiodes PD211 to PD216 which belong to the photoelectric conversion portions.

Moreover, the flat film 220 is formed to have a thickness equal to a thickness of the high absorption layer 280, so as to narrow the gap between the element separation portion (BDTI, etc.) 261 to 267 in the semiconductor substrate 210 (in Si) and the back-side separation portion (BSM, etc.) 271 to 274 on the upper layer of the element separation portion 261 to 267, and make the distance thereof substantially close to zero. In addition, in order to narrow the gap between the element separation portion (BDTI, etc.) 261 to 267 in the semiconductor substrate 210 (in Si) and the back-side separation portion (BSM, etc.) 271 to 274 on the upper layer of the element separation portion 261 to 267 and make the distance thereof substantially close to zero, the guided wave structure 291 including the back-side separation portion such as a BSM is arranged to be embedded between adjacent color filters. In the first embodiment of the present disclosure, the flat film 220 is formed to have a thickness equal to the thickness of the high absorption layer 280. Moreover, in the element separation region between adjacent pixels, the formation region of the element separation portion 261 to 267 and the formation region of the back-side separation portion 271 to 274 are formed in a state of being close to each other (the distance is substantially zero) via the flat film 220.

As such, according to the first embodiment of the present disclosure, crosstalk between pixels can be reduced, and miniaturization of pixel size can be achieved. Moreover, color mixing can be reduced, and high sensitivity and high performance can be achieved.

### Second Embodiment

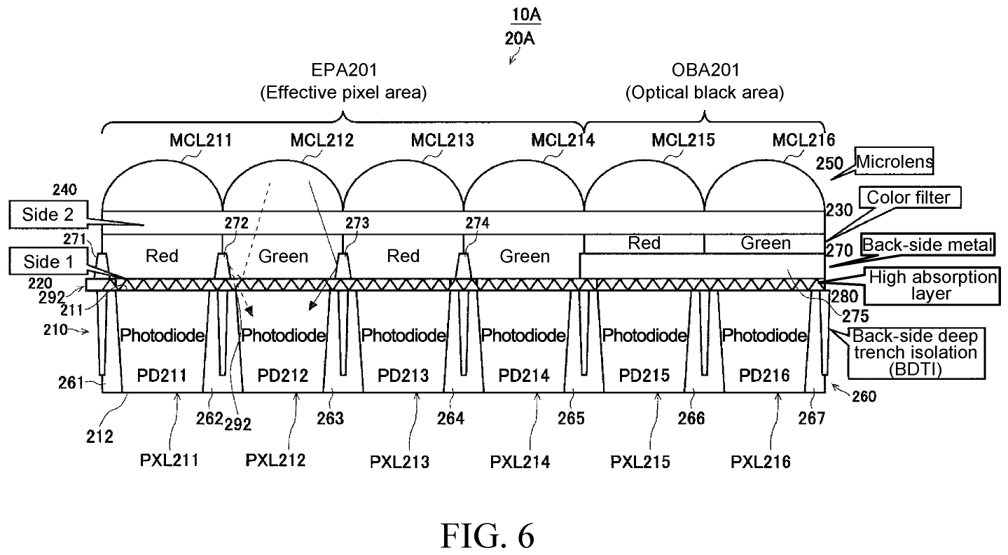

FIG. 6 is a schematic cross-sectional view of each constituent element in a pixel portion of a solid-state imaging apparatus (CMOS image sensor) according to a second embodiment of the present disclosure.

The difference between the second embodiment and the first embodiment is as follows. In the pixel portion 20A of the solid-state imaging apparatus 10A of the second embodiment of the present disclosure, in the peripheral portion of the pixels PXL211 to PXL216, that is, on the high absorption layer (HA layer) 280 of the element separation portion 260 (261 to 267), a scattering property suppression structure 292 for suppressing a scattering property in the guided wave structure 291 including the flat film 220 is formed.

The scattering property suppression structure 292 has the same refractive index as the HA layer 280, and can be partially formed in the HA layer 280 only in this part. Examples of the scattering property suppression structure 292 include high-refractive films made of tantalum oxide (Ta₂O₅), hafnium oxide (HfO₂), aluminum oxide (Al₂O₃), or the like. Besides, a part of or all of the scattering property suppression structure 292 may be formed by the BSM 270.

According to the second embodiment of the present disclosure, not only the same effect as the above-mentioned first embodiment can be obtained, but also crosstalk between pixels can be reduced, and color mixing can be reduced, thereby achieving high sensitivity and high performance.

### Third Embodiment

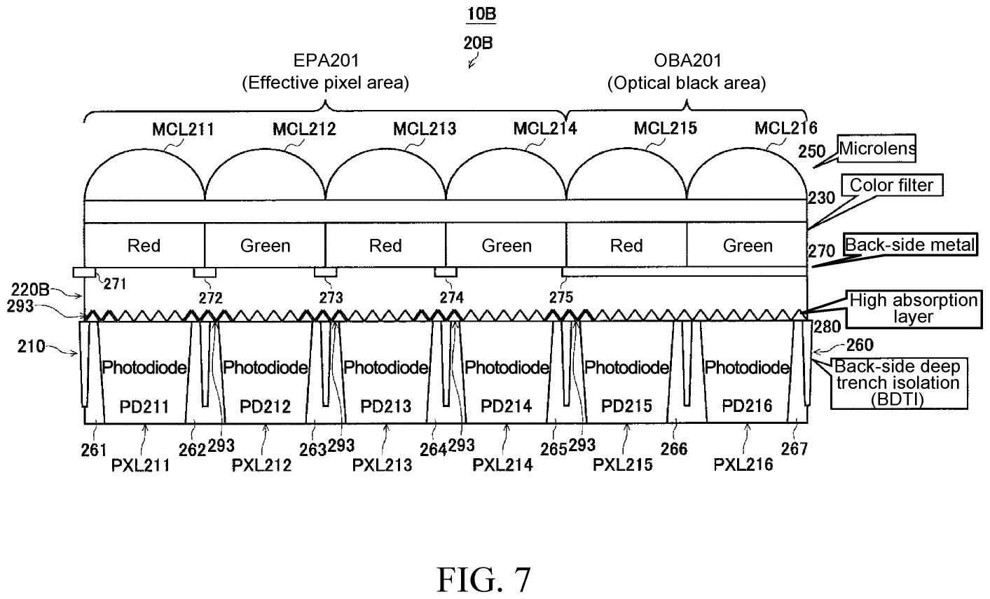

FIG. 7 is a schematic cross-sectional view of each constituent element in a pixel portion of a solid-state imaging apparatus (CMOS image sensor) according to a third embodiment of the present disclosure.

The difference between the third embodiment and the first embodiment is as follows. According to the pixel portion 20B of the solid-state imaging apparatus 10B of the third embodiment of the present disclosure, the peripheral portion of the pixels PXL211 to PXL216—that is, the high absorption layer (HA layer) 280 of the element separation portion 260 (261 to 267), includes a scattering suppression portion 293 that further suppresses a scattering property more than the regions other than the element separation portions 261 to 267 (on one surface of the PD211 to the PD216). In addition, in the third embodiment of the present disclosure, the flat film 220B has a thickness much thicker than a thickness of the high absorption layer 280B. Besides, in the third embodiment of the present disclosure, the back-side separation portions 271 to 274 are not buried between the color filters, but are arranged in a manner that in the joint portion of the lower surface, the reflective surface faces one surface of the semiconductor substrate 210.

An arrangement example of the scattering suppression portion 293 will be described as follows. In the two examples described below, in the element separation region and other regions, the structure of the high absorption layer 280 is given a difference such that the function of the scattering suppression portion 293 is exhibited. For example, in the scattering suppression portion 293, an anti-reflection layer made of one material or a plurality of materials with different refractive indices is formed on the upper region of the high absorption layer 280, and a thickness or a layer structure of the anti-reflection layer on the element separation region is different from a thickness or a layer structure on the region other than the upper region.

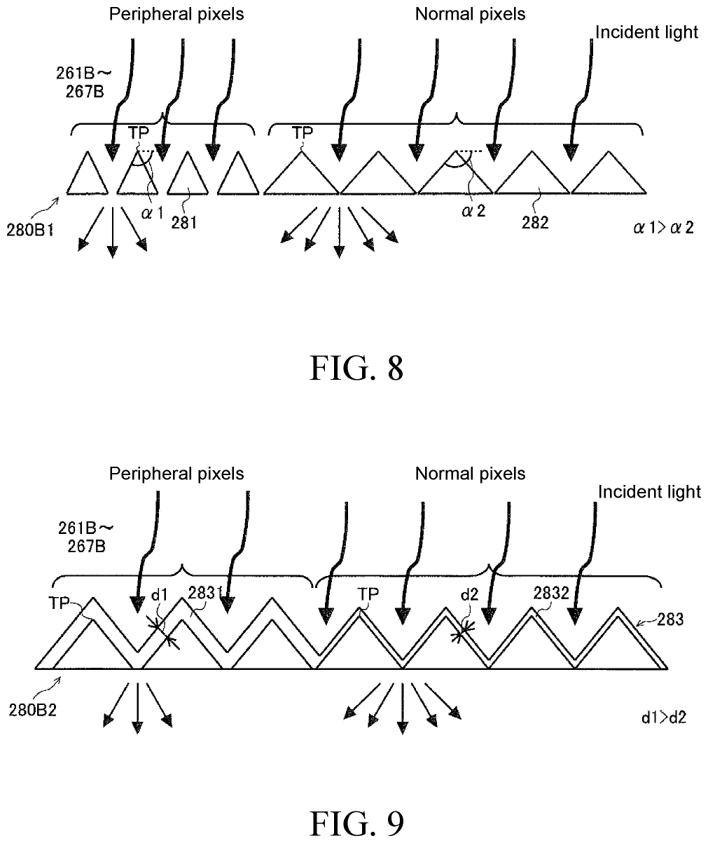

FIG. 8 is a diagram for explaining a first structure example of a scattering suppression portion in a high absorption layer according to the third embodiment of the present disclosure.

The high absorption layer 280B1 in FIG. 8 is formed as a cone-shaped body (a quadrangular cone shape in this example), a top TP thereof is located on a light incident side, and an inclined surface thereof gradually widens toward the one surface side of the semiconductor substrate 210. An inclination angle α1 of an inclined surface of a coned-shaped body 281 arranged on the upper region of the element separation region 261B to 267B is different from an inclination angle α2 of the inclined surface of the cone-shaped body 282 arranged on the region other than the upper region. In this example, the inclination angle α1 of the inclined surface of the coned-shaped body 281 in the upper region of the element separation region 261B to 267B is larger than the inclination angle α2 of the inclined surface of the cone-shaped body 282 in the regions other than the upper region (it becomes an acute angle).

According to the first structure example, the same effect as the above-mentioned first embodiment can be obtained, the scattering of the pixel peripheral region can be suppressed, light can be easily incident on the corresponding pixels, and even shadowing can be suppressed. Accordingly, according to the first structure example, scattering toward the photodiode side can be suppressed, crosstalk between pixels can be reduced, and color mixing can be reduced, thereby achieving high sensitivity and high performance.

FIG. 9 is a diagram for explaining a second structure example of a scattering suppression portion in a high absorption layer according to the third embodiment of the present disclosure.

The high absorption layer 280B2 of FIG. 9 is formed as a cone-shaped body (a quadrangular cone shape in this example), a top TP thereof is located on a light incident side, an inclined surface thereof gradually widens toward the one surface side of the semiconductor substrate 210, and an anti-reflection layer 283 is formed on the inclined surface serving as the light incident surface. The thickness d1 of the anti-reflection layer 2831 formed in the upper region of the element separation region 261B to 267B is different from the thickness d2 of the anti-reflection layer 2832 formed in the regions other than the upper region. In this example, the thickness d1 of the anti-reflection layer 2831 formed in the upper region of the element separation region 261B to 267B is arranged to be thicker than the thickness d2 of the anti-reflection layer 2832 formed in the regions other than the upper region. In this case, scattering at the pixel peripheral portion can also be suppressed, light can be easily incident on the corresponding pixels, and even shadowing can be suppressed. In addition, the anti-reflection layers 2831, 2832 are formed of tantalum oxide (Ta₂O₅), hafnium oxide (HfO₂), aluminum oxide (Al₂O₃), or the like.

In the second structure example, the same effect as the first embodiment described above can be obtained, the scattering toward the photodiode side can be suppressed, crosstalk between pixels can be reduced, and the color mixing can be reduced, thereby achieving high sensitivity and high performance.

### Fourth Embodiment

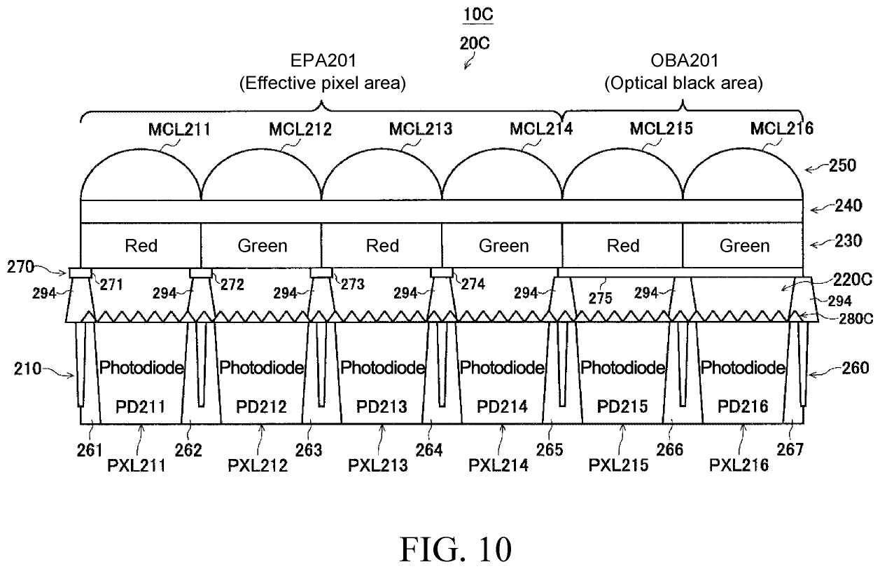

FIG. 10 is a schematic cross-sectional view of each constituent element in a pixel portion 20C of a solid-state imaging apparatus (CMOS image sensor) according to a fourth embodiment of the present disclosure.

The solid-state imaging apparatus 10C of the fourth embodiment is different from the solid-state imaging apparatus 10 of the first embodiment in the following points. In the solid-state imaging apparatus 10C of the fourth embodiment, the flat film 220C has a thickness much thicker than the thickness of the high absorption layer 280C, and is formed to include the high absorption layer 280C. In addition, in the solid-state imaging apparatus 10C of the fourth embodiment, the back-side separation portions 271 to 274 are not buried between the color filters, but are arranged in a manner that in the joint portion of the lower surface, the reflective surface faces one surface of the semiconductor substrate 210. Further, in the solid-state imaging apparatus 10C of the fourth embodiment, in each of the pixels PXL211 to PXL216, a reflection structure 294 for redirecting the diffused light to the corresponding pixel is formed on the upper portion of the element separation portion 261 to 267 formed between the photodiodes (photoelectric conversion portions) of the adjacent pixels.

By arranging such a tubular reflection structure 294, color mixing with respect to pixels can be suppressed. Specifically, by using BSM to form a part of or all of the reflector in the pixel peripheral portion, it is possible to suppress color mixing. The reflector can be formed of back-side metals (Cu, W). Alternatively, the surface of the reflector can also be covered with layers of hafnium oxide, tantalum oxide and/or aluminum oxide with high refraction.

In conclusion, according to the fourth embodiment, color mixing on the photodiode side can be suppressed, crosstalk between pixels can be reduced, and color mixing can be further reduced, thereby achieving high sensitivity and high performance.

### Fifth Embodiment

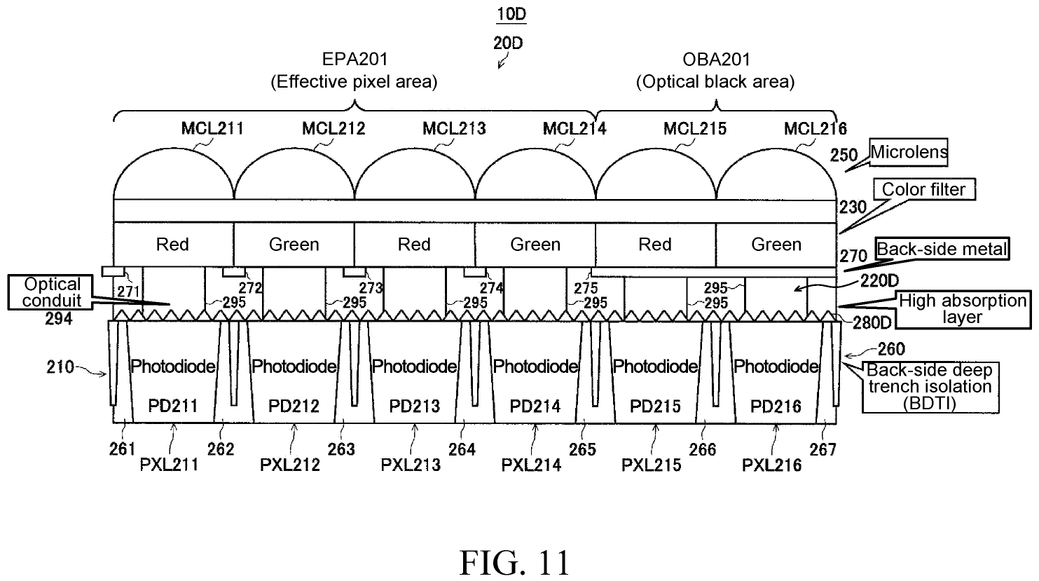

FIG. 11 is a schematic cross-sectional view of each constituent element in a pixel portion 20D of a solid-state imaging apparatus (CMOS image sensor) according to a fifth embodiment of the present disclosure.

The solid-state imaging apparatus 10D of the fifth embodiment is different from the solid-state imaging apparatus 10 of the first embodiment in the following points. In the solid-state imaging apparatus 10D of the fifth embodiment, the flat film 220D has a thickness much thicker than the thickness of the high absorption layer 280D, and is formed to include the high absorption layer 280D. In addition, in the solid-state imaging apparatus 10D of the fifth embodiment, the back-side separation portions 271 to 274 are not buried between the color filters, but are arranged in a manner that in the joint portion of the lower surface, the reflective surface faces one surface of the semiconductor substrate 210. Further, in the solid-state imaging apparatus 10D of the fifth embodiment, the diffused light suppression structure 290 includes a guided wave structure 295 arranged between the light incident side of the high absorption layer 280D and the light exit surface side of the color filters 231 to 234, at the center of the pixels PXL211 to PXL216. The guided wave structure 295 has a higher refractive index than the flat film 220D.

To sum up, according to the fifth embodiment, color mixing on the photodiode side can be suppressed, crosstalk between pixels can be reduced, and color mixing can be further reduced, thereby achieving high sensitivity and high performance.

### Sixth Embodiment

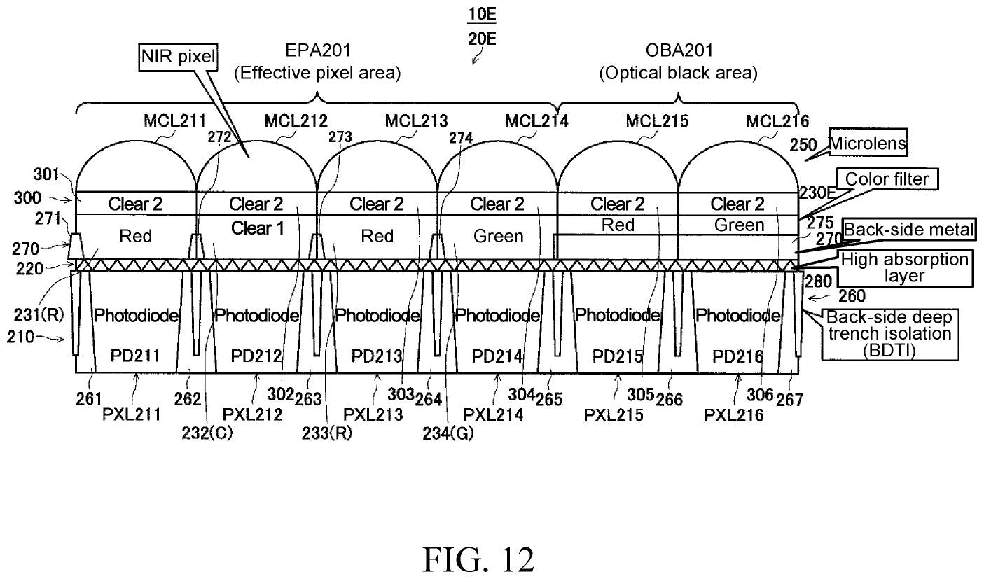

FIG. 12 is schematic cross-sectional view of each constituent element in a pixel portion of a solid-state imaging apparatus (CMOS image sensor) according to a sixth embodiment of the present disclosure.

The solid-state imaging apparatus 10E of the sixth embodiment is different from the solid-state imaging apparatus 10 of the first embodiment in the following points.

In the pixel portion 20E of the solid-state imaging apparatus 10E of the sixth embodiment, the color pixels that receive visible light such as R/G/B, Ye/Cy/Mg, etc., and the pixels that receive non-visible light such as infrared light (IR) are mixed on one chip, and the transmittance of non-visible light pixels relative to the corresponding wavelength is high than that of other pixels.

In the example of FIG. 12, the pixel portion 20E is a mixture of pixels PXL211, PXL213 to PXL216 that receive visible light and pixel PXL212 that receives non-visible light. The transmittance of the photodiode (photoelectric conversion portion) PD212 on one surface side of the non-visible light pixel PXL212 relative to the corresponding wavelength is higher than that of the photodiodes (photoelectric conversion portions) PD211, PD213 to PD216 on one surface side of the visible light pixels PXL211, PXL213 to PXL216 relative to the corresponding wavelength. Further, a wavelength-selective infrared cut filter that blocks infrared light of a specific wavelength is formed by laminating on the color filters arranged on one surface side (the light incident side and the light exit side) of visible light photodiodes (photoelectric conversion portions) PD211, PD213 to PD216. For example, one surface side of the photodiode PD212 (photoelectric conversion portion) of the infrared light receiving pixel PXL212 is formed with a filter layer having infrared sensitivity. That is, the upper portion of the infrared light receiving pixel PXL212 is formed with the clear layers 232, 302.

In the example of FIG. 12, the upper layer (or the lower layer) of the visible light filter array 230E is provided with a second filter array 300 in which the clear layers 301 to 306 are arranged.

In addition, each color pixel having the above-mentioned structure has not only a specific responsiveness in the visible range (400 nm to 700 nm) but also a high responsiveness in the near-infrared (NIR) region (800 nm to 1000 nm).

To sum up, according to the sixth embodiment of the present disclosure, crosstalk between pixels can be reduced, and the sizes of the pixels can be miniaturized. Further, color mixing can be reduced, high sensitivity and high performance can be achieved. It is capable of receiving both visible light and non-visible light, and thus it is even possible to expand the use.

### Seventh Embodiment

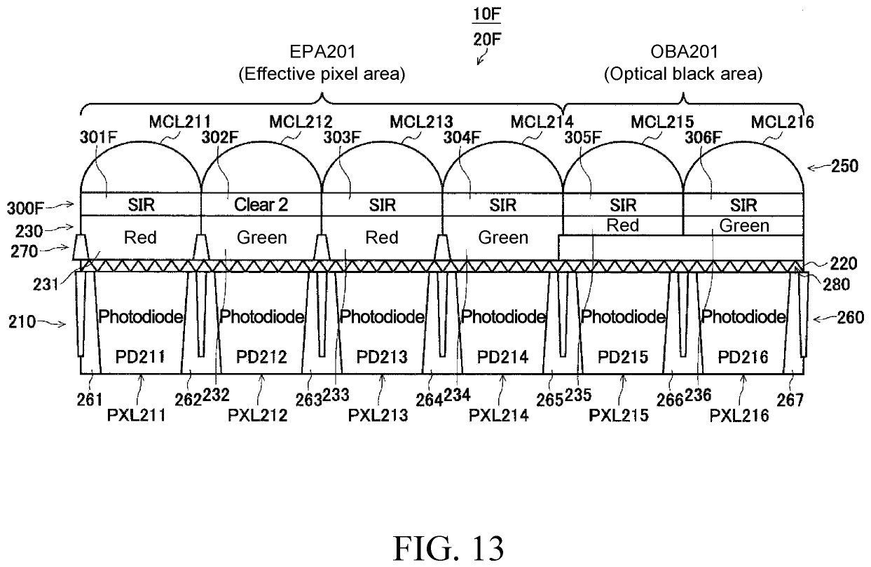

FIG. 13 is schematic cross-sectional view of each constituent element in a pixel portion of a solid-state imaging apparatus (CMOS image sensor) according to a seventh embodiment of the present disclosure.

The solid-state imaging apparatus 10F of the seventh embodiment is different from the solid-state imaging apparatus 10E of the sixth embodiment in the following points.

In the pixel portion 20F of the solid-state imaging apparatus 10F of the seventh embodiment, as in FIG. 5 of the first embodiment, all of color filters 231 (R) to 236 (Gr) are arranged in the filter array 230 so as to correspond to each pixel. The upper portion of the near-infrared (NIR) light receiving pixel PXL212 is formed with the clear layers 232, 302. Additionally, the selective IR cut filters 301F, 303F to 306F are arranged in a manner of being laminated on the color filters to serve as filters for visible light of the second filter array 300F. Moreover, on the infrared pixel can be an IR pass filter or a color filter of various colors with infrared sensitivity.

According to the seventh embodiment, the same effect as that of the sixth embodiment can be obtained, and a camera set without a low pass filter can be realized.

### Eighth Embodiment

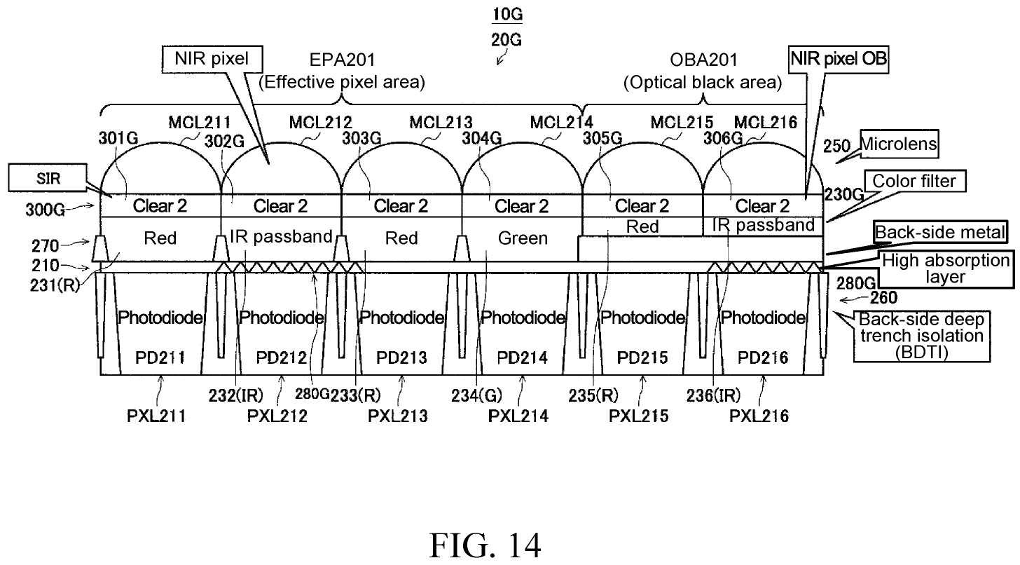

FIG. 14 is a schematic cross-sectional view of each constituent element in a pixel portion of a solid-state imaging apparatus (CMOS image sensor) according to an eighth embodiment of the present disclosure.

The solid-state imaging apparatus 10G of the eighth embodiment is different from the solid-state imaging apparatus 10E of the sixth embodiment in the following points.

In the pixel portion 20G of the solid-state imaging apparatus 10G of the eighth embodiment, it is arranged that the high absorption layer 280G is partially formed on one surface side of the semiconductor substrate 210, and can increase sensitivity without color mixing. More specifically, the high absorption layer 280G is partially formed on one surface side of the photodiode PD212 of the non-visible light pixel PXL212 in the effective pixel area EPA201 and on one surface side of the photodiode PD216 of the light-shielded pixel PXL216 corresponding to the non-visible light pixel in the OB area OBA201. The filter array 230G is arranged with an IR bandpass filter 232 (IR) as a filter corresponding to the non-visible pixel PXL212 in the effective pixel area EPA201. Similarly, an IR bandpass filter 236 (IR) is arranged as a filter corresponding to the pixel PXL216 of the non-visible light in the OB area OBA201.

In the solid-state imaging apparatus 10G having such arrangement, the black reference for the pixels PXL211, PXL213, PXL214 which are not formed with the high absorption layer is the pixel PXL215 in the OB area OBA201 which is not formed with the high absorption layer. On the other hand, the black reference for the pixel PXL212 which is formed with the high absorption layer 280G is the pixel PXL216 in the OB area OBA201 which is formed with the high absorption layer 280G. By adopting the black reference as described above, dark-time noise can be reduced.

According to the eighth embodiment of the present disclosure, the same effect as that of the sixth embodiment can be obtained, sensitivity can be increased without color mixing, and dark-time noise can be reduced.

### Ninth Embodiment

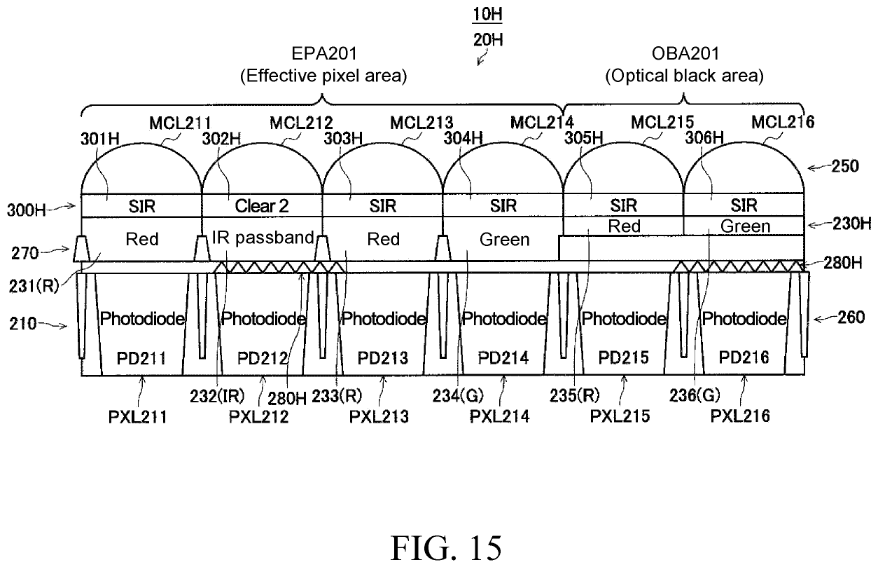

FIG. 15 is a schematic cross-sectional view of each constituent element in a pixel portion of a solid-state imaging apparatus (CMOS image sensor) according to a ninth embodiment of the present disclosure.

The solid-state imaging apparatus 10H of the ninth embodiment is different from the solid-state imaging apparatus 10F of the seventh embodiment in the following points.

In the pixel portion 20H of the solid-state imaging apparatus 10H of the ninth embodiment, it is arranged that the high absorption layer 280H is partially formed on one surface side of the semiconductor substrate 210, and can increase sensitivity without color mixing. More specifically, the high absorption layer 280H is partially formed on one surface side of the photodiode 212 of the non-visible light pixel PXL212 in the effective pixel area EPA201 and on one surface side of the photodiode PD216 of the light shielded pixel PXL216 corresponding to the non-visible light pixel in the OB area OBA201. The filter array 230H is arranged with an IR bandpass filter 232 (IR) as a filter corresponding to the non-visible pixel PXL212 in the effective pixel area EPA201. On the other hand, as a filter corresponding to the non-visible light pixel PXL216 of the OB area OBA201, a color filter 236 (Gr) is arranged similar to FIG. 13 of the seventh embodiment.

In the solid-state imaging apparatus 10H having such arrangement, the black reference for the pixels PXL211, PXL213, PXL214 which are not formed with the high absorption layer is the pixel PXL215 in the OB area OBA201 which is not formed with the high absorption layer. On the other hand, the black reference for the pixel PXL212 which is formed with the high absorption layer 280H is the pixel PXL216 in the OB area OBA201 which is formed with the high absorption layer 280H. By adopting the black reference as described above, dark-time noise can be reduced.

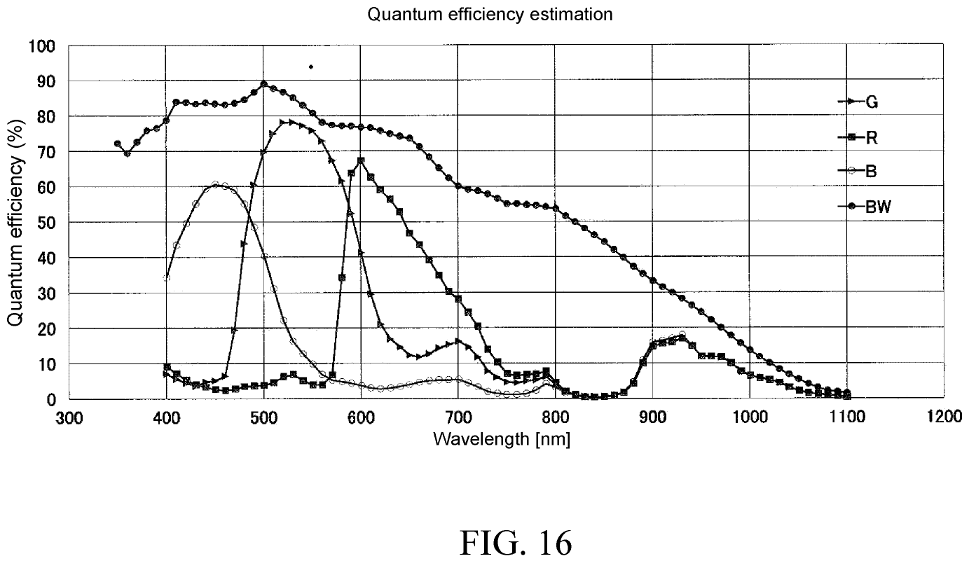

FIG. 16 is a graph showing the quantum efficiency (%) performance with respect to the wavelength of incident light of the solid-state imaging apparatus (CMOS image sensor) according to the ninth embodiment of the present disclosure. In FIG. 16, an abscissa represents the wavelength (nm), and an ordinate represents the quantum efficiency (QE (%)).

As shown in FIG. 16, the solid-state imaging apparatus 10H of the ninth embodiment can transmit visible light such as RGB and infrared light of a specific wavelength and receive light at a photodiode PD (photoelectric conversion portion). Specific infrared wavelengths are 800 nm to 1000 nm. That is, the solid-state imaging apparatus 10H has not only a specific responsiveness in the visible range (400 nm to 700 nm) but also a high responsiveness in the near-infrared (NIR) region (800 nm to 1000 nm).

According to the ninth embodiment of the present disclosure, the same effect as that of the seventh embodiment can be obtained, sensitivity can be increased without color mixing, and dark-time noise can be reduced.

### Tenth Embodiment

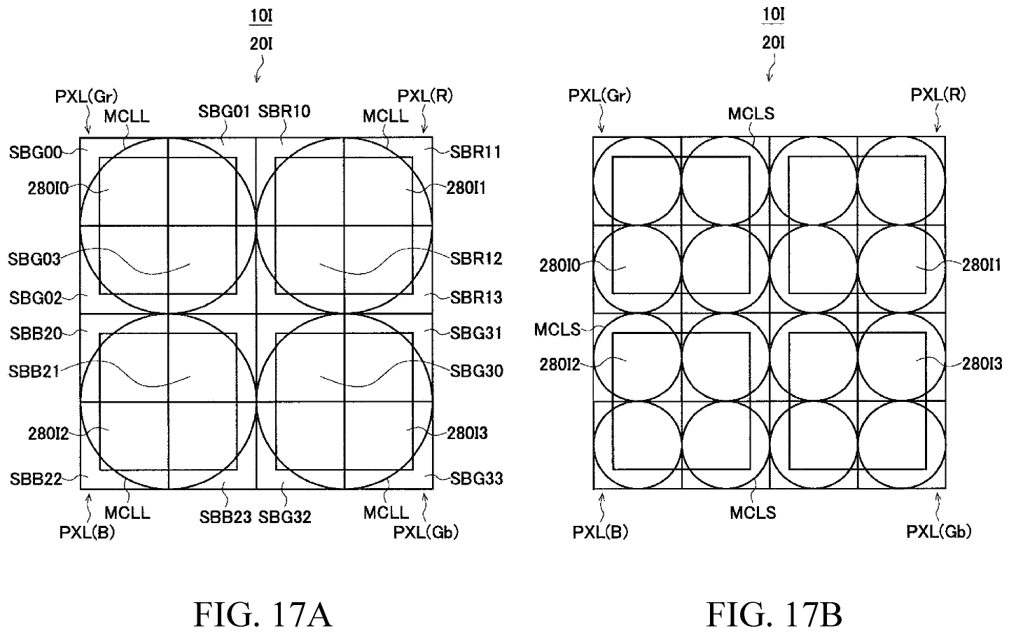

FIGS. 17A and B are diagrams showing a schematic arrangement example of each constituent element in the pixel portion of the solid-state imaging apparatus (CMOS image sensor) in a plane view according to a tenth embodiment of the present disclosure.

In the solid-state imaging apparatus 10I of the tenth embodiment, the pixel portion 20I is arranged to include an arrangement in which pixels of the same color are adjacent to each other.

In this example, the green pixel PXL(Gr), the red pixel PXL(R), the blue pixel PXL(B) and the green pixel PXL(Gb) are arranged in a 2×2 matrix. Moreover, the green pixel PXL(Gr) are arranged with a 2×2 matrix of four same-color subpixels SBG00, SBG01, SBG02, SBG03 adjacent to each other. The red pixel PXL(R) are arranged with a 2×2 matrix of four same-color subpixels SBR10, SBR11, SBR12, SBR13 adjacent to each other. The blue pixel PXL(B) are arranged with a 2×2 matrix of four same-color subpixels SBB20, SBB21, SBB22, SBB23 adjacent to each other. The green pixel PXL(Gb) are arranged with a 2×2 matrix of four same-color subpixels SBG30, SBG31, SBG32, SBG33 adjacent to each other.

In the example of FIG. 17A, one microlens MCLL is arranged for four same-color subpixels. In the example of FIG. 17B, one microlens MCLS is arranged for each of four same-color subpixels.

Further, in the solid-state imaging apparatus 10I, the high absorption layer 280I is formed on the same-color subpixel matrix in a manner of being separated (non-contact) from other subpixel matrices of different colors. Specifically, the high absorption layer 28010 is formed across the four same-color subpixels SBG00, SBG01, SBG02, SBG03. The high absorption layer 28011 is formed across the four same-color subpixels SBR10, SBR11, SBR12, SBR13. The high absorption layer 28012 is formed across the four same-color subpixels SBB20, SBB21, SBB22, SBB23. The high absorption layer 280I3 is formed across the four same-color subpixels SBG30, SBG31, SBG32, SBG33.

### Eleventh Embodiment

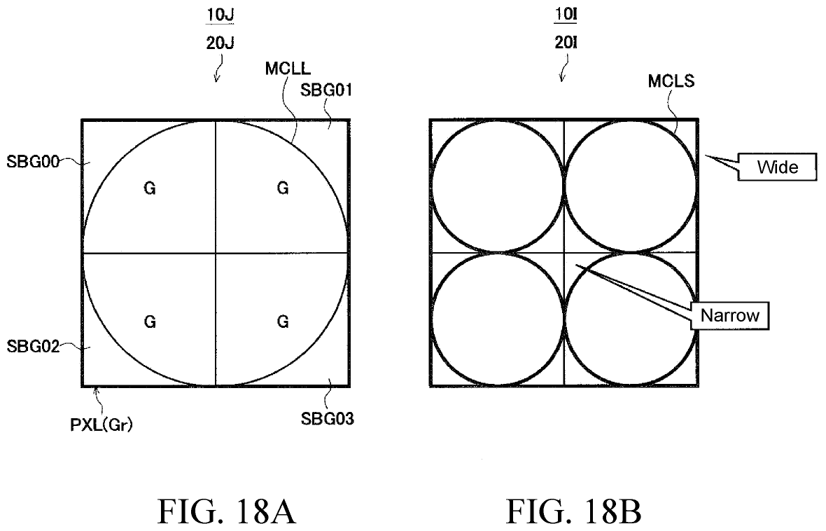

FIGS. 18A and B are diagrams showing a schematic arrangement example of each constituent element in the pixel portion of the solid-state imaging apparatus (CMOS image sensor) in a plane view according to an eleventh embodiment of the present disclosure.

In the solid-state imaging apparatus 10J of the tenth embodiment, the pixel portion 20J is arranged to include an arrangement in which pixels of the same color are adjacent to each other.

In this example, the green pixel PXL(Gr), the red pixel PXL(R), the blue pixel PXL(B) and the green pixel PXL(Gb) are arranged in a 2×2 matrix. As an example, the green pixel PXL(Gr) is arranged with a 2×2 matrix with four same-color subpixels SBG00, SBG01, SBG02, SBG03 adjacent to each other. Although not shown, the red pixel PXL(R), the blue pixel PXL(B) and the green pixel PXL(Gb) are also arranged in the same manner.

In the example of FIG. 18A, one microlens MCL is arranged for four same-color subpixels. In the example of FIG. 18B, one microlens MCLS is arranged for each of four same color subpixels.

Additionally, in the solid-state imaging apparatus 10J, as described in the above-mentioned first embodiment and the like, the pixel end (pixel peripheral region) is formed with a scattering suppression structure such as BSM, which is a diffused light suppression structure to suppress scattering by the high absorption layer 280J. In the eleventh embodiment, the width of the scattering suppression structure formed at the pixel boundary between same colors is narrower than the width of the scattering suppression structure formed at the pixel boundary between different colors.

The scattering suppression structure is a structure that suppresses the scattering light which occurs in the light absorption layer 280J and is generated in the direction of the substrate surface, at the pixel end. By adopting this structure, color mixing between pixels receiving different wavelengths that have a great influence on image quality can be selectively suppressed such that high sensitivity and reduction of crosstalk can be achieved at the same time.

The solid-state imaging apparatus 10 and 10A to 10J described above can be used as a camera device to be applied to electronic devices such as digital cameras, camcorders, mobile terminal apparatus, surveillance cameras and medical endoscope cameras.

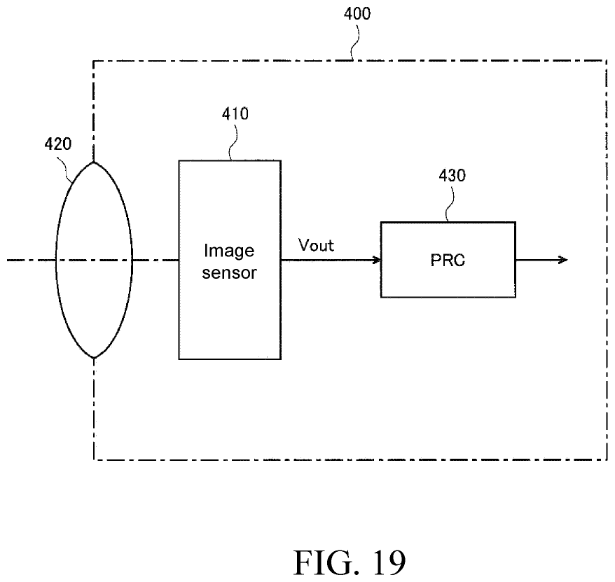

FIG. 19 is a diagram showing a structure example of an electronic device equipped with a camera system to which the solid-state imaging apparatus according to the present disclosure is applied.

As shown in FIG. 19, the electronic device 400 has a CMOS image sensor 410 to which the solid-state imaging apparatus 10 and 10A to 10J of the present disclosure can be applied. In addition, the electronic device 400 has an optical system (a lens, etc.) 420 that guides incident light (imaging of an object) to the pixel area of the CMOS image sensor 410. The electronic device 400 has a signal processing circuit (PRC) 430 for processing the output signal of the CMOS image sensor 410.

The signal processing circuit 430 performs predetermined signal processing on the output signal of the CMOS image sensor 410. The image signals processed by the signal processing circuit 430 are displayed as animations on a monitor composed of a liquid crystal display, etc., or may be outputted to a printer. Additionally, the image signals can also be directly recorded in various recording media such as a memory card.

In summary, the present disclosure can provide a high-performance, small-sized and low-cost camera system by mounting the aforementioned solid-state imaging apparatus 10 and 10A to 10J as the CMOS image sensor 410. Besides, the present disclosure can realize electronic device such as surveillance cameras, medical endoscope cameras, etc., which are used in applications where the installation requirements of the camera have restrictions on the installation size, the number of cables that can be connected, the cable length and the installation height, etc.

What is claimed is:

1. A solid-state imaging apparatus, comprising:
a pixel portion in which a plurality of pixels, at least each for visible light and each for performing photoelectric conversion, are arranged in a matrix,
the pixel portion including:
a filter array arranged with at least a plurality of color filters for visible light;
a plurality of photoelectric conversion portions for visible light corresponding to at least the plurality of color filters, provided with a function of photoelectric conversing light that passes through each of the color filters arranged on one surface side and outputting charges obtained by photoelectric conversion;
a high absorption layer arranged on one surface side of the photoelectric conversion portions, for controlling a reflection component of incident light on a surface of the one surface side of the photoelectric conversion portions, and re-diffusing the incident light in the photoelectric conversion portions; and
a diffused light suppression structure for suppressing diffused light in a light incident path toward one surface side of the photoelectric conversion portions including the high absorption layer.

2. The solid-state imaging apparatus according to claim 1, wherein the diffused light suppression structure includes a flat film formed between one surface side of the photoelectric conversion portions and a light exit surface side of the filters, and the flat film is formed to have a thickness equal to a thickness of the high absorption layer.

3. The solid-state imaging apparatus according to claim 1, wherein each pixel is formed with an element separation portion which is formed between the photoelectric conversion portions of adjacent pixels, and the diffused light suppression structure includes a guided wave structure for redirecting diffused light to the pixels in an upper part of the element separation portion of each pixel.

4. The solid-state imaging apparatus according to claim 3, wherein the guided wave structure includes a back-side separation portion, and the back-side separation portion is formed to include the space between adjacent filters so as to separate a plurality of adjacent pixels at least in light incident portions of the photoelectric conversion portions.

5. The solid-state imaging apparatus according to claim 4, wherein the diffused light suppression structure includes a flat film formed between one surface side of the photoelectric conversion portions and a light exit surface side of the filters, and the flat film is formed to have a thickness equal to a thickness of the high absorption layer,
in an element separation area between adjacent pixels, a formation region of the element separation portion and a formation region of the back-side separation portion are formed in a state of being close to each other via the flat film.

6. The solid-state imaging apparatus according to claim 2, wherein a scattering property suppression structure for suppressing a scattering property in the guided wave structure is formed in the high absorption layer located on an upper region of the element separation portion.

7. The solid-state imaging apparatus according to claim 1, wherein the high absorption layer located on the upper region of the element separation portion includes a scattering suppression portion that further suppresses a scattering property more than the high absorption layer located on regions other than the upper region.

8. The solid-state imaging apparatus according to claim 7, wherein the high absorption layer is formed as a cone-shaped body, a top thereof is located on a light incident side, and an inclined surface thereof gradually widens toward the surface side, and
an inclination angle of an inclined surface of a coned-shaped body arranged on the upper region is different from an inclination angle of the inclined surface of the cone-shaped body arranged on the region other than the upper region.

9. The solid-state imaging apparatus according to claim 8, wherein the inclination angle of the inclined surface of the coned-shaped arranged on the upper region is larger than the inclination angle of the inclined surface of the cone-shaped body arranged on the region other than the upper region.

10. The solid-state imaging apparatus according to claim 7, wherein an anti-reflection layer made of one material or a plurality of materials with different refractive indices is formed on the upper region of the high absorption layer, and a thickness or a layer structure of the anti-reflection layer on the element separation region is different from a thickness or a layer structure on the region other than the upper region.

11. The solid-state imaging apparatus according to claim 10, wherein the high absorption layer is formed as a cone-shaped body, a top thereof is located on a light incident side, and an inclined surface thereof gradually widens toward the surface side, and an anti-reflection layer is formed on the inclined surface which serves as a light incident surface, and
the thickness of the anti-reflection layer formed on the upper region is different from the thickness of the anti-reflection layer formed on the region other than the upper region.

12. The solid-state imaging apparatus according to claim 11, wherein the thickness of the anti-reflection layer formed on the upper region is thicker than the thickness of the anti-reflection layer formed on the region other than the upper region.

13. The solid-state imaging apparatus according to claim 1, wherein in each of the pixels, an element separation portion is formed between the photoelectric conversion portions of adjacent pixels, and
the diffused light suppression structure includes a reflection structure for redirecting diffused light to the pixels in an upper part of the element separation portion of each pixel.

14. The solid-state imaging apparatus according to claim 1, wherein the pixel portion includes a flat film between one surface side of the photoelectric conversion portions and a light emitting surface side of the color filters, the flat film is formed to include the high absorption layer,
the diffused light suppression structure includes a guided wave structure arranged between a light incident side of the high absorption layer and the light emitting surface of the filters, at central portions of the pixels, and
a reflection index of the guided wave structure is higher than a reflection index of the flat film.

15. The solid-state imaging apparatus according to claim 1, the pixel portion contains a mixture of pixels that receive visible light and pixels that receive non-visible light, and
a transmittance of one surface side of the photoelectric conversion portions of non-visible light pixels relative a corresponding wavelength is higher than a transmittance of one surface side of the photoelectric conversion portions of visible light pixels relative to a corresponding wavelength.

16. The solid-state imaging apparatus according to claim 1, wherein the pixel portion contains a mixture of pixels that receive visible light and pixels that receive non-visible light,
a transmittance of one surface side of the photoelectric conversion portions of non-visible light pixels relative to a corresponding to wavelength is high than a transmittance of one surface side of the photoelectric conversion portions of visible light pixels relative to a corresponding wavelength, and
a selective infrared layer or an infrared cut filter layer is formed by laminating on the light incident side or the light emitting side of the color filters arranged on one surface side of the photoelectric conversion portions for visible light.

17. The solid-state imaging apparatus according to claim 15, wherein one surface side of the photoelectric conversion portion of an infrared light-receiving pixel is formed with a filter layer having infrared sensitivity.

18. The solid-state imaging apparatus according to claim 15, wherein the filter layer is formed by a clear layer.

19. The solid-state imaging apparatus according to claim 1, wherein the pixel portion contains a mixture of pixels that receive visible light and pixels that receive non-visible light, and
one surface side of the photoelectric conversion portions of the non-visible light pixels is partially formed with the high absorption layer.

20. The solid-state imaging apparatus according to claim 19, wherein a wavelength-selective infrared cut filter for blocking infrared light of a specific wavelength is formed by laminating on the color filters of light-receiving pixels of visible light.

21. The solid-state imaging apparatus according to claim 19, wherein a peripheral region of the pixel portion includes an optical black area, and
the high absorption layer is partially formed on one surface side of the photoelectric conversion portions of light-shielded pixels corresponding to the non-visible light pixel in the optical black area.

22. The solid-state imaging apparatus according to claim 21, wherein a black reference for pixels in which the high absorption layer is not formed is an optical black pixel in which the high absorption layer is not formed in the optical black area, and
a black reference for pixels in which the high absorption layer is formed is an optical black pixel in which the high absorption layer is formed in the optical black area.

23. The solid-state imaging apparatus according to claim 1, wherein the pixel portion includes an arrangement in which pixels with the same color are arranged adjacent to each other, and
the high absorption layer is formed across groups of a plurality of adjacent pixels with the same color in a non-contact state with other groups of pixels.

24. The solid-state imaging apparatus according to claim 1, wherein the pixel portion includes an arrangement in which pixels with the same color are arranged adjacent to each other,
ends of the pixels are formed with a scattering suppression structure for suppressing scattering caused by the high absorption layer, and
a width of the scattering suppression structure at a pixel boundary between same colors is narrower than a width of the scattering suppression structure at a pixel boundary between different colors.

25. The solid-state imaging apparatus according to claim 1, wherein the pixel portion includes: an effective pixel area in which pixels are to be photoelectrically converted; and a peripheral area arranged around the effective pixel area.

26. The solid-state imaging apparatus according to claim 25, wherein the peripheral area of the pixel portion includes an optical black area.

27. A method for manufacturing a solid-state imaging apparatus,
the solid-state imaging apparatus including:
a pixel portion in which a plurality of pixels, at least each for visible light and each for performing photoelectric conversion, are arranged in a matrix,
the pixel portion including:
a filter array, a plurality of photoelectric conversion portions for visible light, a high absorption layer, and a diffused light suppression structure;
as a step of forming the pixel portion, the method including the steps of:
forming the filter array by arranging at least a plurality of color filters for visible light on one surface side of the plurality of photoelectric conversion portions for visible light;
forming the plurality of photoelectric conversion portions for visible light as corresponding to at least the plurality of color filters and being provided with a function of photoelectric conversing light that passes through each of the color filters arranged on one surface side and outputting charges obtained by photoelectric conversion;
forming on the one surface side of the photoelectric conversion portions, the high absorption layer for controlling a reflection component of incident light on a surface of the one surface side of the photoelectric conversion portions, and re-diffusing the incident light in the photoelectric conversion portions; and
forming the diffused light suppression structure for suppressing diffused light in a light incident path toward one surface side of the photoelectric conversion portions including the high absorption layer.

28. An electronic device, comprising:
a solid-state imaging apparatus; and
an optical system configured for imaging an object in the solid-state imaging apparatus,
the solid-state imaging apparatus including:
a pixel portion in which a plurality of pixels, at least each for visible light and each for performing photoelectric conversion, are arranged in a matrix,
the pixel portion including:
a filter array arranged with at least a plurality of color filters for visible light;
a plurality of photoelectric conversion portions for visible light corresponding to at least the plurality of color filters, provided with a function of photoelectric conversing light that passes through each of the color filters arranged on one surface side and outputting charges obtained by photoelectric conversion;
a high absorption layer arranged on one surface side of the photoelectric conversion portions, for controlling a reflection component of incident light on a surface of the one surface side of the photoelectric conversion portions, and re-diffusing the incident light in the photoelectric conversion portions; and
a diffused light suppression structure for suppressing diffused light in a light incident path toward one surface side of the photoelectric conversion portions including the high absorption layer.
